(19) United States
(12) Patent Application Publication
(10) Pub. No.: US 2026/0026358 A1
(43) Pub. Date: Jan. 22, 2026

(54) SEMICONDUCTOR PACKAGE

(71) Applicant: SAMSUNG ELECTRONICS CO., LTD., SUWON-SI (KR)

(72) Inventors: SANGKYU LEE, SUWON-SI (KR); WOOSANG JUNG, SUWON-SI (KR)

(21) Appl. No.: 19/051,532

(22) Filed: Feb. 12, 2025

(30) Foreign Application Priority Data
Jul. 22, 2024 (KR) 10-2024-0096721

(51) Int. Cl. H01L 23/544; H01L 23/00; H01L 23/31; H01L 23/538; H01L 25/07; H01L 25/11

(52) U.S. Cl. CPC H01L 23/544; H01L 23/3107; H01L 24/13; H01L 24/16; H01L 25/074; H01L 25/117; H01L 23/538; H01L 2223/54426; H01L 2224/13082; H01L 2224/16227; H01L 2225/06517; H01L 2225/06562

(57) ABSTRACT

A semiconductor package includes a package substrate, a first chip group including at least one first chip spaced apart from the package substrate in a first direction perpendicular to a surface of the package substrate, a second chip group including at least one second chip disposed between the package substrate and the first chip group, a first molding film that surrounds the first chip group, a second molding film that surrounds the second chip group, and an alignment post that penetrates the first molding film and contacts the second molding film. The second molding film covers a surface of an end portion of the alignment post facing the package substrate.

### CROSS-REFERENCE TO RELATED APPLICATIONS

This application claims priority under 35 U.S.C. § 119 to Korean Patent Application No. 10-2024-0096721, filed on Jul. 22, 2024, the disclosure of which is incorporated by reference herein in its entirety.

### TECHNICAL FIELD

Example embodiments relate to a semiconductor package.

### DISCUSSION OF RELATED ART

With the rapid development of the electronics industry, there is a growing demand for high-performance, high-speed, and miniaturized electronic components. To meet this demand, methods have been developed to stack and mount multiple semiconductor chips in a single package wiring structure or by stacking packages on top of one another. For example, a package-in-package (PIP) type semiconductor package or a package-on-package (POP) type semiconductor package can be used.

As semiconductor packages become more highly integrated, vertical distribution structures are increasingly utilized, in which semiconductor chips are stacked vertically and the semiconductor chips are electrically connected.

### SUMMARY

Embodiments of the present disclosure provide a semiconductor package having improved alignment accuracy.

Embodiments of the present disclosure provide a miniaturized semiconductor package.

According to an embodiment of the present disclosure, a semiconductor package includes a package substrate, a first chip group including at least one first chip spaced apart from the package substrate in a first direction perpendicular to a surface of the package substrate, a second chip group including at least one second chip disposed between the package substrate and the first chip group, a first molding film that surrounds the first chip group, a second molding film that surrounds the second chip group, and an alignment post that penetrates the first molding film. The second molding film covers a surface of an end portion of the alignment post facing the package substrate.

According to an embodiment of the present disclosure, a semiconductor package includes a package substrate, a first chip group including at least one first chip spaced apart from the package substrate in a first direction perpendicular to a surface of the package substrate, a second chip group including at least one second chip disposed between the package substrate and the first chip group, a first molding film that surrounds the first chip group, a second molding film that surrounds the second chip group, an insulating film disposed on the first molding film in the first direction, an alignment pad disposed in the first molding film and in contact with the insulating film, and an alignment post that overlaps the alignment pad in the first direction. The alignment post penetrates the first molding film, and the alignment post overlaps the second molding film in the first direction.

According to an embodiment of the present disclosure, a semiconductor package includes a package substrate, a first chip group including at least one first chip spaced apart from the package substrate in a first direction perpendicular to a surface of the package substrate, a second chip group including at least one second chip disposed between the package substrate and the first chip group, a first molding film that surrounds the first chip group, a second molding film that surrounds the second chip group, a first distribution post extending in the first direction between the at least one first chip and the package substrate, a second distribution post extending in the first direction between the at least one second chip and the package substrate, an alignment pad disposed on the first chip group in the first direction and disposed in the first molding film, and an alignment post that overlaps the alignment pad in the first direction, penetrates the first molding film. The second molding film covers a surface of the alignment post facing the package substrate, the first distribution post includes a first part that penetrates the first molding film and a second part that penetrates the second molding film, and is connected to the first part, and a surface of an end portion of the first part facing the package substrate and a surface of an end portion of the second part facing the first chip are in contact with each other. In a second direction crossing the first direction, a width of the end portion of the first part facing the package substrate and a width of the end portion of the second part facing the first chip are different, and a surface of an end portion of the first molding film facing the package substrate and a surface of an end portion of the second molding film facing the first chip group are in contact with each other.

According to example embodiments, the alignment accuracy of semiconductor packages may be improved.

According to example embodiments, a miniaturized semiconductor package may be provided.

### BRIEF DESCRIPTION OF THE DRAWINGS

The above and other features of the present disclosure will become more apparent by describing in detail embodiments thereof with reference to the accompanying drawings, in which:

FIG. 1 is a drawing illustrating a semiconductor package according to an example embodiment;

FIG. 2 is a drawing illustrating a semiconductor package according to an example embodiment;

FIG. 3 is a drawing illustrating a semiconductor package according to an example embodiment;

FIG. 4 is a drawing illustrating a semiconductor package according to an example embodiment;

FIG. 5 is a drawing illustrating a semiconductor package according to an example embodiment;

FIG. 6 is a drawing illustrating a semiconductor package according to an example embodiment; and

FIGS. 7 to 20 are drawings illustrating intermediate operations performed in a method of manufacturing a semiconductor package according to some example embodiments.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each example embodiment should typically be considered as available for other similar features or aspects in other example embodiments, unless the context clearly indicates otherwise.

As used herein, the singular forms “a”, “an” and “the” are intended to include the plural forms as well, unless the context clearly indicates otherwise.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

The terms “have,” “may have,” “include,” and “may include” as used herein indicate the presence of corresponding features (for example, elements such as numerical values, functions, operations, and parts), and do not preclude the presence of additional features.

Example embodiments of the present disclosure address challenges in the alignment and stacking of semiconductor chips within highly integrated and miniaturized semiconductor packages. Conventional approaches, which typically rely on intermediate wiring layers such as middle redistribution layers (MRDLs), introduce issues such as increased package thickness and reduced alignment accuracy due to the use of double alignment processes. As a result, the development of smaller, more efficient semiconductor packages may be hindered.

Example embodiments of the present application may remove the need for intermediate wiring layers by instead using alignment structures, such as alignment posts and pads, that are directly integrated into the molding films. For example, an alignment post may penetrate the molding film and serve as a precise reference point for aligning vertically stacked chip groups, resulting in improved accuracy during the manufacturing process. By encapsulating the chips within molding films while leveraging alignment posts, example embodiments may also eliminate the need for double alignment, which typically reduces alignment precision.

Example embodiments may provide electrical connectivity and structural integrity of the semiconductor chips, as well as reduce the overall thickness of the semiconductor package in the stacking direction, thereby enabling miniaturization. Thus, example embodiments of the present disclosure may provide improved structural and alignment mechanisms that can improve manufacturing efficiency, alignment accuracy, and overall performance, while addressing the growing demand for high-performance and compact electronic components.

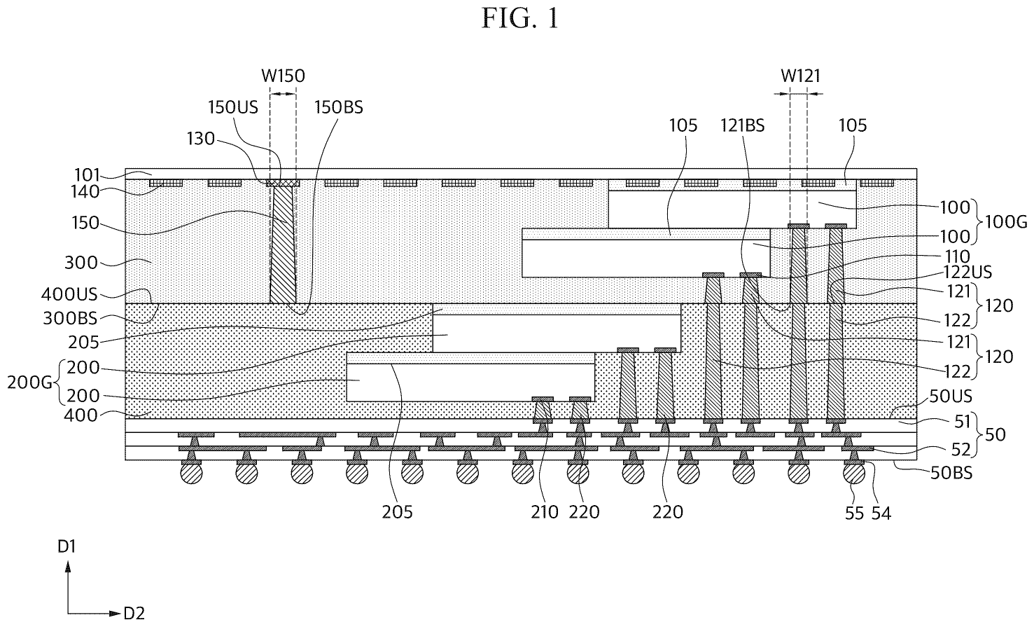

FIG. 1 is a drawing illustrating a semiconductor package according to an example embodiment.

Referring to FIG. 1, the semiconductor package may include a package substrate 50, a first chip group 100G, a first distribution post 120, a second chip group 200G, a second distribution post 220, a first molding film 300, a second molding film 400, an alignment pad 130, a dummy pad 140 and a first alignment post 150.

According to some example embodiments, the package substrate 50 may be a wiring structure for a package. For example, the package substrate 50 may be a printed circuit board (PCB), a ceramic substrate, or an interposer. According to some example embodiments, the package substrate 50 may be a distribution structure for a wafer level package (WLP) manufactured at a wafer level.

According to some example embodiments, the package substrate 50 may function as a redistribution layer. For example, the package substrate 50 may be the front redistribution layer (FRDL) of a fan-out package.

In some example embodiments, the package substrate 50 may be, for example, a glass substrate, a ceramic substrate or a plastic substrate, but the package substrate 50 is not limited thereto. For example, according to some example embodiments, the package substrate 50 may include a resin impregnated in a core material such as glass fiber (e.g., glass cloth and glass fabric) with an inorganic filler, for example, prepreg, an ajinomoto build-up film (ABF), or FR-4, and bismaleimide triazine (BT).

According to some example embodiments, the package substrate 50 may include a redistribution insulating film 51 and a redistribution structure 52.

According to some example embodiments, when the package substrate 50 is a PCB, the redistribution insulating film 51 may be made of at least one of, for example, phenol resin, epoxy resin and polyimide. The package substrate 50 may include at least one of, for example, tetrafunctional epoxy, polyphenylene ether, epoxy/polyphenylene oxide, bismaleimide triazine (BT), thermount, cyanate ester and liquid crystal polymer.

In some example embodiments, the redistribution insulating film 51 may include a photoimageable dielectric. The photoimageable dielectric may be, for example, a material that can be patterned or imaged using light exposure, for example, as part of a photolithography process. For example, the redistribution insulating film 51 may include a photosensitive polymer. The photosensitive polymer may be formed of at least one of, for example, a photosensitive polyimide, a polybenzoxazole, a phenol-based polymer, and a benzocyclobutene-based polymer. In an example embodiment, the redistribution insulating film 51 may be formed of, for example, a silicon oxide film, a silicon nitride film, or a silicon oxynitride film.

According to some example embodiments, the redistribution insulating film 51 may include multiple laminated insulating films. For example, as illustrated in FIG. 1, the redistribution insulating film 51 may include a plurality of insulating films stacked in the first direction D1. Each of the plurality of insulating films may surround the distribution pattern and distribution via of the redistribution structure 52, which will be described in further detail below.

According to some example embodiments, the surface of the redistribution insulating film 51 may be covered with solder resist. For example, a passivation film may be formed on the surface of the redistribution insulating film 51. The passivation film formed on the surface of the redistribution insulating film 51 may protect the redistribution structure 52 and other structures from external impact or moisture. The passivation film may include solder resist. However, example embodiments of the present disclosure are not limited thereto.

According to some example embodiments, the redistribution structure 52 may be disposed within the redistribution insulating film 51. The redistribution structure 52 may include distribution patterns and distribution vias that connect each distribution pattern. For example, the redistribution structure 52 may be a multilayer structure in which two or more distribution patterns or two or more distribution vias are alternately stacked. The distribution pattern is part of the horizontal connection between conductive components, and the distribution vias may be part of vertical connections between conductive components. For example, the distribution pattern may extend in the second direction D2. The distribution via may connect distribution patterns spaced in the first direction D1. Here, the first direction D1 may refer to a direction perpendicular to the surface of the package substrate 50. For example, the first direction D1 may indicate a direction perpendicular to a bottom surface 50BS of the package substrate or an upper surface 50US of the package substrate.

In some example embodiments, the redistribution structure 52 may include a conductive material. For example, the redistribution structure 52 may include copper (Cu), aluminum (Al), silver (Ag), tin (Sn), gold (Au), nickel (Ni), lead (Pb), titanium (Ti), or alloys thereof. However, the redistribution structure 52 is not limited thereto.

According to some example embodiments, an external connection terminal 55 may be formed on the bottom surface 50BS of the package substrate. The external connection terminal 55 may be disposed on an external connection pad 54. The external connection terminal 55 may make contact with the external connection pad 54. In an example embodiment, the external connection terminal 55 may include a solder ball or a solder bump. In an example embodiment, the external connection terminal 55 may include a micro bump. The shape of the external connection terminal 55 may be spherical or elliptical, but is not limited thereto. The number, spacing, arrangement, and shape of the external connection terminal 55 are not limited to what is illustrated in the drawings. For example, the number, spacing, arrangement, and shape of the external connection terminal 55 may vary depending on the design. For example, the external connection terminal 55 may include tin (Sn), indium (In), bismuth (Bi), antimony (Sb), copper (Cu), silver (Ag), zinc (Zn), lead (Pb), and combinations thereof, but the external connection terminal 55 is not limited thereto.

According to some example embodiments, the external connection terminal 55 may electrically connect the redistribution structure 52 to an external device. Accordingly, the external connection terminal 55 may provide electrical signals to the redistribution structure 52, or provide an electrical signal from the redistribution structure 52 to an external device.

For example, the external connection terminal 55 may provide electrical signals for a first chip 100 and a second chip 200. The external connection terminal 55 may receive signals that are input to the first chip 100 and the second chip 200. The external connection terminal 55 may receive the signals output from the first chip 100 and the second chip 200.

According to some example embodiments, the first chip group 100G may be disposed on the package substrate 50 in the first direction D1. For example, first chips 100 of the first chip group 100G may be stacked in the first direction D1. The first chip group 100G may be disposed on the second chip group 200G in the first direction D1. For example, first chips 100 of the first chip group 100G may be located above second chips 200 of the second chip group 200G in the first direction D1. The first chip group 100G may be arranged further away from the package substrate 50 than the second chip group 200G in the first direction D1. For example, a distance between the first chip group 100G and the package substrate 50 may be greater than a distance between the second chip group 200G and the package substrate 50. The first chip group 100G may be disposed within the first molding film 300.

According to some example embodiments, the first chip group 100G may include at least one first chip 100. For example, the first chip group 100G may include multiple first chips 100. For example, the first chip group 100G may include two first chips 100. The first chips 100 may be disposed on the package substrate 50 in the first direction D1. FIG. 1 illustrates that the first chip group 100G includes two first chips 100, but example embodiments are not limited thereto. For example, according to some example embodiments, the first chip group 100G may include only one first chip 100 or may include three or more first chips 100.

For example, when the first chip group 100G includes a plurality of first chips 100, the plurality of first chips 100 may be arranged offset from each other in the second direction D2. The expression “be arranged offset” may indicate that the plurality of first chips 100 are placed to be crossed at a set interval. For example, the plurality of first chips 100 may be placed to cross each other in the second direction D2 in order for the first chips 100 not to be completely overlapping each other in the first direction D1, by some portion of each of the first chips 100 overlapping in the first direction D1, and the other portion of each of the first chips 100 not overlapping in the first direction D1. The sidewalls of the plurality of first chips 100 may be placed to be spaced apart at regular intervals without being disposed on the same plane. As a result of the plurality of first chips 100 being offset in the second direction D2, according to some example embodiments, a first connection pad 110 disposed in each of the plurality of first chips 100 does not overlap other first chips 100 in the first direction D1. Therefore, each first connection pad 110 may be connected to the first distribution post 120.

For example, when the first chip group 100G includes multiple first chips 100, these chips may be arranged in an offset manner along the second direction D2. Being “arranged offset” means that the first chips 100 are positioned such that they cross each other at defined intervals. In this arrangement, the first chips 100 may partially overlap each other in the first direction D1, with some portions of each first chip 100 overlapping in the first direction D1 while other portions remain non-overlapping. The sidewalls of the first chips 100 may be spaced apart at regular intervals, such that they are not positioned on the same horizontal plane. This offset arrangement in the second direction D2 results in the first connection pads 110 on each first chip 100 not overlapping with other first chips 100 in the first direction D1. As a result, each first connection pad 110 can independently connect to a corresponding first distribution post 120.

According to some example embodiments, the first chip 100 may include the first connection pad 110. The first connection pad 110 may be disposed on a bottom surface of the first chip 100. Here, the bottom surface of the first chip 100 may refer to one side of the first chip 100 facing the package substrate 50. The first connection pad 110 may be exposed on the bottom surface of the first chip 100. The first connection pad 110 may contact the first distribution post 120. The first connection pad 110 may be electrically connected to the first distribution post 120.

For example, according to some example embodiments, the first chip 100 may include a first connection pad 110 located on its bottom surface. The bottom surface of the first chip 100 may refer to the side that faces the package substrate 50. This connection pad 110 may be exposed on the bottom surface of the first chip 100, allowing it to make direct contact with the first distribution post 120. The first connection pad 110 may be electrically connected to the first distribution post 120, facilitating the transmission of electrical signals between the first chip 100 and the distribution post.

According to some example embodiments, the first chip 100 may be fixed within the first molding film 300 through a first adhesive layer 105. The first adhesive layer 105 may be disposed on the upper surface of the first chip 100. The upper surface of the first chip 100 may refer to the surface opposite to the bottom surface of the first chip 100 that faces the package substrate 50. The first adhesive layer 105 may fix the first chips 100 to each other. Further, the first adhesive layer 105 may secure the first chip 100 that is the most spaced apart from the second chip group 200G to the first direction D1 onto the alignment pad 130, the dummy pad 140 and an insulating film 101. The first adhesive layer 105 disposed on the first chip 100 that is the most spaced apart from the second chip group 200G to the first direction D1 may cover at least one of the dummy pads 140.

For example, according to some embodiments, the first chip 100 may be secured within the first molding film 300 using a first adhesive layer 105. This first adhesive layer 105 may be applied to the upper surface of the first chip 100, which is opposite to its bottom surface that faces the package substrate 50. The first adhesive layer 105 may not only bond multiple first chips 100 together, but may also secure the uppermost first chip 100—furthest from the second chip group 200G in the first direction D1—to the alignment pad 130, the dummy pad 140, and an insulating film 101. Additionally, the first adhesive layer 105 applied to this uppermost chip may cover at least one of the dummy pads 140.

According to some example embodiments, the first distribution post 120 may be extended to the first direction D1 between the first chip 100 and the package substrate 50. The first distribution post 120 may be disposed on the first chip 100 in the first direction D1. For example, the first distribution post 120 may be disposed on the bottom surface of the first chip 100 in the first direction D1. The first distribution post 120 may electrically connect the first chip 100 and the package substrate 50.

For example, according to some embodiments, the first distribution post 120 may extend in the first direction D1 between the first chip 100 and the package substrate 50, and may be positioned on the bottom surface of the first chip 100, which faces the package substrate 50. The first distribution post 120 may serve to electrically connect the first chip 100 to the package substrate 50, enabling the transmission of signals or power between the two.

According to some example embodiments, the first distribution post 120 may be disposed on the first connection pad 110. The first distribution post 120 may be disposed on one side of the first connection pad 110 exposed from the bottom surface of the first chip 100 in the first direction D1. The first distribution post 120 may be disposed between the first connection pad 110 and the package substrate 50. By connecting the first connection pad 110 and the redistribution structure 52, the first distribution post 120 may electrically connect the second chip 200 and the package substrate 50.

For example, according to some example embodiments, the first distribution post 120 may be positioned on the first connection pad 110. For example, in the first direction D1, the first distribution post 120 may be located on one side of the first connection pad 110, which is exposed on the bottom surface of the first chip 100. The first distribution post 120 may be situated between the first connection pad 110 and the package substrate 50. By linking the first connection pad 110 to the redistribution structure 52, the first distribution post 120 may enable electrical connectivity between the second chip 200 and the package substrate 50.

According to some example embodiments, the first distribution post 120 may penetrate the first molding film 300 and the second molding film 400. The first distribution post 120 may be surrounded by the first molding film 300 and the second molding film 400. For example, the sidewalls of the first distribution post 120 may be surrounded by the first molding film 300 and the second molding film 400.

According to some example embodiments, the first distribution post 120 may include metal materials such as, for example, titanium (Ti), copper (Cu), aluminum (Al), silver (Ag), tin (Sn), gold (Au), nickel (Ni), lead (Pb) and alloys thereof. FIG. 1 illustrates that the first distribution post 120 is a single film, but the first distribution post 120 is not limited thereto. For example, the first distribution post 120 may have a multi-layer structure.

According to some example embodiments, the first distribution post 120 may include a first part 121 and a second part 122. The first part 121 and the second part 122 may be distinguished based on the interface where the first molding film 300 and the second molding film 400 come into contact.

According to some example embodiments, the first part 121 may be disposed within the first molding film 300. The first part 121 may penetrate the first molding film 300. The first part 121 may be surrounded by the first molding film 300. According to some example embodiments, the first part 121 may overlap the first molding film 300 in the second direction D2, and the first part 121 does not overlap the second molding film 400 in the second direction D2.

According to some example embodiments, the first part 121 may be disposed on the second part 122 in first direction D1. For example, the first part 121 may be disposed on an upper surface 122US of the second part in the first direction D1. The first part 121 may be connected to the second part 122.

According to some example embodiments, the first part 121 may have a width that increases in the second direction D2 as the first part 121 approaches the package substrate 50 in the first direction D1. For example, in a cross section including the first direction D1 and the second direction D2, the first part 121 may have a trapezoidal shape. A bottom surface 121BS of the first part may be wider than the upper surface of the first part 121. The bottom surface 121BS of the first part may refer to the end surface of the first part 121 facing the package substrate 50. The bottom surface 121BS of the first part may refer to one side of the first part 121 that contacts the second part 122. The upper surface of the first part 121 may be the opposite surface to the bottom surface 121BS of the first part, and may refer to one side of the first part 121 that contacts the first connection pad 110.

For example, according to some example embodiments, the first part 121 may have a width that increases in the second direction D2 as it approaches the package substrate 50 in the first direction D1. For example, in a cross-sectional view along the first direction D1 and the second direction D2, the first part 121 may have a trapezoidal shape. The bottom surface 121BS of the first part 121, which faces the package substrate 50, may be wider than its upper surface. The bottom surface 121BS refers to the end surface of the first part 121 that makes contact with the second part 122. Conversely, the upper surface of the first part 121, which is opposite the bottom surface 121BS, refers to the side that makes contact with the first connection pad 110.

According to some example embodiments, the second part 122 may be disposed within the second molding film 400. The second part 122 may penetrate the second molding film 400. The second part 122 may be surrounded by the second molding film 400. According to some example embodiments, the second part 122 may overlap the second molding film 400 in the second direction D2, and does not overlap the first molding film 300 in the second direction D2.

According to some example embodiments, the second part 122 may be disposed on a lower side of the first part 121 in the first direction D1. For example, the second part 122 may be disposed on the bottom surface 121BS of the first part in the first direction D1. The second part 122 may be connected to the first part 121.

According to some example embodiments, the second part 122 may have a width that increases in the second direction D2 as the second part 122 approaches the package substrate 50 in the first direction D1. For example, in a cross section including the first direction D1 and the second direction D2, the second part 122 may have a trapezoidal shape. The upper surface 122US of the second part may be smaller in width than the bottom surface of the second part 122. The upper surface 122US of the second part may refer to the end surface of the second part 122 facing the first chip 100. The upper surface 122US of the second part may refer to one side of the second part 122 that contacts the first part 121. The bottom surface of the second part 122 may be the opposite surface to the upper surface 122US of the second part, and may refer to one side of the second part 122 that contacts the package substrate 50.

For example, according to some example embodiments, the second part 122 may have a width that increases in the second direction D2 as it approaches the package substrate 50 in the first direction D1. For example, in a cross-sectional view along the first direction D1 and the second direction D2, the second part 122 may have a trapezoidal shape. The upper surface 122US of the second part 122, which faces the first chip 100, may be narrower than its bottom surface. The upper surface 122US refers to the end surface of the second part 122 that makes contact with the first part 121. Conversely, the bottom surface of the second part 122, which is opposite the upper surface 122US, refers to the side that makes contact with the package substrate 50

According to some example embodiments, the first part 121 and the second part 122 may be in direct contact with each other. For example, the first part 121 and the second part 122 may be directly connected to each other without mediating other components. The bottom surface 121BS of the first part and the upper surface 122US of the second part may contact each other. For example, the bottom surface 121BS of the first part may refer to one side of the first part 121 facing the package substrate 50. The upper surface 122US of the second part may refer to one side of the second part 122 facing the first chip 100. The bottom surface 121BS of the first part and the upper surface 122US of the second part may have different widths in the second direction D2. For example, in the second direction D2, the width of the bottom surface 121BS of the first part may be greater than the width of the upper surface 122US of the second part.

For example, according to some example embodiments, the first part 121 and the second part 122 may be in direct contact with each other, without any intervening components. For example, the bottom surface 121BS of the first part and the upper surface 122US of the second part may make direct contact. The bottom surface 121BS of the first part refers to the side facing the package substrate 50, while the upper surface 122US of the second part refers to the side facing the first chip 100. These surfaces may have different widths in the second direction D2. For example, the width of the bottom surface 121BS of the first part in the second direction D2 may be greater than the width of the upper surface 122US of the second part.

According to some example embodiments, the second chip group 200G may be disposed on the package substrate 50 in the first direction D1. For example, second chips 200 of the second chip group 200G may be stacked in the first direction D1. The second chip group 200G may be disposed on a lower side of the first chip group 100G in the first direction D1. The second chip group 200G may be disposed between the first chip group 100G and the package substrate 50. The second chip group 200G may be placed closer to the package substrate 50 than the first chip group 100G in the first direction D1. For example, a distance between the second chip group 200G and the package substrate 50 may be less than a distance between the first chip group 100G and the package substrate 50. The second chip group 200G may be disposed within the second molding film 400.

According to some example embodiments, the second chip group 200G may include at least one second chip 200. For example, the second chip group 200G may include multiple second chips 200. For example, the second chip group 200G may include two second chips 200. The second chips 200 may be disposed on the package substrate 50 in the first direction D1. FIG. 1 illustrates that the second chip group 200G includes two second chips 200, but the present disclosure is not limited thereto. For example, according to some example embodiments, the second chip group 200G may include only one second chip 200 or may include three or more second chips 200.

For example, when the second chip group 200G includes a plurality of second chips 200, the plurality of second chips 200 may be arranged offset from each other in the second direction D2. For example, the plurality of second chips 200 may be placed to cross each other in the second direction D2 in order for the first chips 100 not to be completely overlapping each other in the first direction D1, by some portion of each of the first chips 100 being overlapping in the first direction D1, and the other portion of each of the first chips 100 not overlapping in the first direction D1. The sidewalls of the plurality of second chips 200 may be spaced apart from each other at regular intervals without being disposed on the same plane. As a result of the plurality of second chips 200 being offset in the second direction D2, according to some example embodiments, a second connection pad 210 arranged in each of the plurality of second chips 200 does not overlap other second chips 200 in the first direction D1. Therefore, each second connection pad 210 may be connected to the second distribution post 220.

For example, according to some example embodiments, when the second chip group 200G includes multiple second chips 200, these second chips 200 may be arranged in an offset manner along the second direction D2. This arrangement allows the second chips 200 to cross each other in the second direction D2 such that the first chips 100 are not entirely overlapping in the first direction D1. Instead, portions of each first chip 100 overlap in the first direction D1, while other portions do not. The sidewalls of the second chips 200 are spaced apart at regular intervals, avoiding placement on the same horizontal plane. Due to this offset arrangement in the second direction D2, according to some example embodiments, each second connection pad 210 in the second chips 200 does not overlap other second chips 200 in the first direction D1. As a result, each second connection pad 210 can be independently connected to a corresponding second distribution post 220.

According to some example embodiments, the second chip 200 may include the second connection pad 210. The second connection pad 210 may be disposed on the bottom surface of the second chip 200. Here, the bottom surface of the second chip 200 may refer to one side of the second chip 200 facing the package substrate 50. The second connection pad 210 may be exposed on the bottom surface of the second chip 200. The second connection pad 210 may contact the second distribution post 220. The second connection pad 210 may be electrically connected to the second distribution post 220.

According to some example embodiments, the second chip 200 may be fixed within the second molding film 400 via a second adhesive layer 205. The second adhesive layer 205 may be disposed on the upper surface of the second chip 200. The upper surface of the second chip 200 may refer to the surface opposite to the bottom surface of the second chip 200 that faces the package substrate 50. The second adhesive layer 205 may secure the second chips 200 to each other. Further, the second adhesive layer 205 may secure the second chips 200, which are closest to the first chip group 100G in the first direction D1, onto the first molding film 300. The second adhesive layer 205, which is disposed on the second chip 200 most adjacent to the first chip group 100G in the first direction D1, may be in contact with the first molding film 300.

According to some example embodiments, the first adhesive layer 105 and the second adhesive layer 205 may include, for example, a non-conductive film (NCF), a non-conductive paste (NCP), an insulating polymer or the epoxy resin. However, example embodiments of the present disclosure are not limited thereto. For example, the first adhesive layer 105 and the second adhesive layer 205 may be tapes configured to fix the first chip 100 and the second chip 200 to each other. The first adhesive layer 105 and the second adhesive layer 205 may be tapes including, for example, an epoxy component.

According to some example embodiments, the second distribution post 220 may extend to the first direction D1 between the second chip 200 and the package substrate 50. The second distribution post 220 may be disposed on the second chip 200 in the first direction D1. For example, the second distribution post 220 may be disposed on the bottom surface of the second chip 200 in the first direction D1. The second distribution post 220 may electrically connect the second chip 200 and the package substrate 50.

According to some example embodiments, the second distribution post 220 may be disposed on the second connection pad 210. The second distribution post 220 may be disposed on one side of the second connection pad 210 exposed on the bottom surface of the second chip 200 in the first direction D1. The second distribution post 220 may be disposed between the second connection pad 210 and the package substrate 50. By connecting the second connection pad 210 and the redistribution structure 52, the second distribution post 220 may electrically connect the second chip 200 and the package substrate 50.

According to some example embodiments, the second distribution post 220 may penetrate the second molding film 400. The second distribution post 220 may be surrounded by the second molding film 400. For example, the sidewall of the second distribution post 220 may be surrounded by the second molding film 400. The second distribution post 220 may increase in width in the second direction D2 as the second distribution post 220 approaches the package substrate 50 in the first direction D1. For example, in a cross section including the first direction D1 and the second direction D2, the second distribution post 220 may have a trapezoidal shape.

According to some example embodiments, the second distribution post 220 may include a metal material such as titanium (Ti), copper (Cu), aluminum (Al), silver (Ag), tin (Sn), gold (Au), nickel (Ni), lead (Pb), and an alloy thereof. FIG. 1 illustrates that the distribution post 220 is a single layer, but the distribution post 220 is not limited thereto. For example, according to some example embodiments, the second distribution post 220 may have a multi-membrane structure.

According to some example embodiments, each of the first chip 100 and the second chip 200 may include an integrated circuit (IC). The first chip 100 and the second chip 200 may have an active surface on which the IC is formed and an inactive surface disposed on the opposite side of the active surface. The active surface may be referred to as the front side surface, and the inactive surface may be referred to as the back side surface. For example, the front side surface may refer to the surface facing the package substrate 50, and the inactive surface may refer to a surface that is opposite to the front side surface.

According to some example embodiments, the first chip 100 and the second chip 200 may be semiconductor memory chips. According to some example embodiments, the semiconductor memory chip may be, for example, a volatile memory, such as dynamic random access memory (DRAM) and static random access memory (SRAM). According to some example embodiments, the semiconductor memory chip may be a non-volatile memory, such as, for example, flash memory, phase-change random access memory (PRAM), magnetic random access memory (MRAM), ferroelectric random access memory (FeRAM) and resistive random access memory (RRAM). However, example embodiments are not limited thereto.

For example, at least some of the first chips 100 and the second chips 200 may be logic semiconductor chips. The logic semiconductor chip may be an application processor (AP) such as, for example, a central processing unit (CPU), a graphic processing unit (GPU), a field-programmable gate array (FPGA), a digital signal processor, an encryption processor, a microprocessor, a microcontroller and an application-specific IC (ASIC).

According to some example embodiments, the first molding film 300 may be disposed on the second molding film 400. The first molding film 300 may be disposed on an upper surface 400US of the second molding film in the first direction D1. The first molding film 300 may be positioned further away from the package substrate 50 than the second molding film 400 in the first direction D1.

According to some example embodiments, the first molding film 300 may surround the first chip group 100G. The first molding film 300 may cover the first chip group 100G. The first molding film 300 may surround the first chip 100, the first part 121 of the first distribution post 120, and the first alignment post 150. The first molding film 300 may fill the space between the first chip 100 and the second chip 200. For example, at least a portion of the first molding film 300 may be disposed between the first chip 100 most adjacent to the second chip group 200G and the second chip 200 most adjacent to the first chip group 100G.

According to some example embodiments, the second molding film 400 may be placed at a lower portion of the first molding film 300. The second molding film 400 may be disposed on a bottom surface 300BS of the first molding film in the first direction D1. The second molding film 400 may cover a bottom surface 150BS of the first alignment post 150. For example, the second molding film 400 may cover the bottom surface 150BS of an end portion of the first alignment post 150 facing the package substrate 50. For example, the first alignment post 150 may fully penetrate the first molding film 300 such that the bottom surface 150BS (e.g., an end portion) of the first alignment post 150 facing the package substrate 50 contacts the second molding film 400. The bottom surface 150BS of the first alignment post 150 may refer to the end surface of the first alignment post 150 facing the package substrate 50. The second molding film 400 may overlap the first alignment post 150 in the first direction D1. The second molding film 400 may be disposed between the first molding film 300 and the package substrate 50. The second molding film 400 may be disposed on the package substrate 50. The second molding film 400 may cover the upper surface 50US of the package substrate.

According to some example embodiments, the second molding film 400 may surround the second chip group 200G. The second molding film 400 may cover the second chip group 200G. The second molding film 400 may surround the second chip 200, the second distribution post 220 and the second part 122 of the first distribution post 120.

According to some example embodiments, the first molding film 300 and the second molding film 400 may be in contact with each other. For example, the bottom surface 300BS of the first molding film and the upper surface 400US of the second molding film may be in contact with each other. The bottom surface 300BS of the first molding film may refer to the surface of the first molding film 300 facing the package substrate 50. The upper surface 400US of the second molding film may refer to the surface of the second molding film 400 facing the first chip group 100G.

According to some example embodiments, the first molding film 300 and the second molding film 400 may include an insulating material. In an example embodiment, the first molding film 300 and the second molding film 400 may include an insulating polymer material such as an epoxy molding compound (EMC). In an example embodiment, the first molding film 300 and the second molding film 400 may include a thermosetting resin such as the epoxy resin or a thermoplastic resin such as a polyimide. The first molding film 300 and the second molding film 400 may include filler. The filler contents included in the first molding film 300 and the second molding film 400 may be different.

According to some example embodiments, the alignment pad 130 may be disposed within the first molding film 300. The alignment pad 130 may be covered by the first molding film 300. The alignment pad 130 may be disposed on the first chip group 100G in the first direction D1. The alignment pad 130 may be disposed on the insulating film 101. For example, in the first direction D1, the alignment pad 130 may be disposed on the bottom surface of the insulating film 101 facing the package substrate 50. According to some example embodiments, the alignment pad 130 does not overlap the first chip 100 and the first direction D1.

For example, according to some example embodiments, the alignment pad 130 may be positioned within the first molding film 300 and covered by the first molding film 300. The alignment pad 130 may be located on the first chip group 100G along the first direction D1 and disposed on the insulating film 101. For example, in the first direction D1, the alignment pad 130 may be situated on the bottom surface of the insulating film 101, which faces the package substrate 50. Additionally, in some embodiments, the alignment pad 130 does not overlap with the first chip 100 in the first direction D1.

According to some example embodiments, the alignment pad 130 may be used to align the first chips 100. Aligning may indicate setting positions around a reference point in order for the first chips 100 to be disposed in preset positions. For example, the first chips 100 may be aligned on the insulating film 101 using the alignment pad 130 as a reference point.

According to some example embodiments, the dummy pad 140 may be disposed within the first molding film 300. The dummy pad 140 may be covered by the first molding film 300. The dummy pad 140 may be disposed on the first chip group 100G in the first direction D1. The dummy pad 140 may be disposed on the insulating film 101. For example, in the first direction D1, the dummy pad 140 may be disposed on the bottom surface of the insulating film 101 facing the package substrate 50.

According to some example embodiments, the dummy pad 140 may be placed to be spaced apart from the alignment pad 130 in the second direction D2. According to some example embodiments, the dummy pad 140, unlike the alignment pad 130, is not used as a reference point when aligning the first chip 100. Some dummy pads 140 may overlap the first chip 100 in the first direction D1. At least some of dummy pads 140 may be disposed in the first adhesive layer 105. The dummy pad 140 may relieve deformation or shrinkage of the first adhesive layer 105.

According to some example embodiments, the alignment pad 130 and the dummy pad 140 may have the same shape. For example, when viewed in the first direction D1, the shapes of the alignment pad 130 and the dummy pad 140 may be identical or substantially similar. In an example embodiment, the shapes of the alignment pad 130 and the dummy pad 140 may be, for example, circular, square, and so on, and the alignment pad 130 and the dummy pad 140 may have the same shape and the same size. In an example embodiment, the alignment pad 130 and the dummy pad 140 may have different forms. The alignment pad 130 and the dummy pad 140 may include a metal material such as, for example, copper (Cu), aluminum (Al), titanium (Ti), silver (Ag), tin (Sn), gold (Au), nickel (Ni), lead (Pb), and an alloy thereof. In an example embodiment, the alignment pad 130 and the dummy pad 140 may include the same material. In an example embodiment, the alignment pad 130 and the dummy pad 140 may include different materials.

According to some example embodiments, the insulating film 101 may be disposed on the alignment pad 130 in the first direction D1. The insulating film 101 may be disposed on the first molding film 300 in the first direction D1. The insulating film 101 may face the package substrate 50 with the first molding film 300 and the second molding film 400 interposed therebetween.

According to some example embodiments, the insulating film 101 may include, for example, a photoimageable dielectric material. In an example embodiment, the insulating film 101 may include a photosensitive polymer. The photosensitive polymer may be formed of at least one of, for example, a photosensitive polyimide, a polybenzoxazole, a phenol-based polymer, and a benzocyclobutene-based polymer. In an example embodiment, the insulating film 101 may be formed of, for example, a silicon oxide film, a silicon nitride film, or a silicon oxynitride film.

According to some example embodiments, the first alignment post 150 may penetrate the first molding film 300. The first alignment post 150 may overlap the first molding film 300 in the second direction D2. The first alignment post 150 may be disposed on the alignment pad 130. The first alignment post 150 may extend between the alignment pad 130 and the second molding film 400.

According to some example embodiments, the first alignment post 150 does not penetrate the second molding film 400. The first alignment post 150 may overlap the second molding film 400 in the first direction D1. The bottom surface 150BS of the first alignment post 150 may be covered by the second molding film 400. The bottom surface 150BS of the first alignment post 150 may contact the second molding film 400. An upper surface 150US of the first alignment post 150 may contact the alignment pad 130.

According to some example embodiments, the first alignment post 150 does not overlap the second chip 200 in the first direction D1. The first alignment post 150 may be offset from the first chip 100 in the second direction D2.

According to some example embodiments, the first alignment post 150 may increase in width in the second direction D2 as the first alignment post 150 approaches the package substrate 50 in the first direction D1. For example, in a cross section including the first direction D1 and the second direction D2, the first alignment post 150 may have a trapezoidal shape. The width of the bottom surface 150BS of the first alignment post 150 may be greater than the width of the upper surface 150US of the alignment post in the second direction D2.

For example, according to some example embodiments, the first alignment post 150 may increase in width along the second direction D2 as it approaches the package substrate 50 in the first direction D1. In a cross-sectional view along the first direction D1 and the second direction D2, the first alignment post 150 may have a trapezoidal shape. For example, the width of the bottom surface 150BS of the alignment post, which faces the package substrate, may be greater than the width of the upper surface 150US in the second direction D2.

According to some example embodiments, in the second direction D2, the maximum width W150 of the first alignment post 150 may be different from the maximum width W121 of the first part 121 of the first distribution post 120. The width of the bottom surface 150BS of the first alignment post 150 and the width of the bottom surface 121BS of the first part of the first distribution post 120 may be different in the second direction D2. For example, the width of the bottom surface 150BS of the first alignment post 150 may be greater than the width of the bottom surface 121BS of the first part.

According to some example embodiments, the bottom surface 150BS of the alignment post, the bottom surface 300BS of the first molding film, and the bottom surface 121BS of the first part of the first distribution post 120 may be arranged on the same plane. This alignment may result from a manufacturing process of semiconductor packages in which a grinding operation is performed on the first alignment post 150, the first molding film 300, and the first part 121 of the first distribution post 120 through the same process.

According to some example embodiments, the first alignment post 150 may include a metal material such as, for example, titanium (Ti), copper (Cu), aluminum (Al), silver (Ag), tin (Sn), gold (Au), nickel (Ni), lead (Pb), and an alloy thereof. For example, the first alignment post 150 may include the same material as the first distribution post 120. The first alignment post 150 may include the same material as the first part 121 of the first distribution post 120. FIG. 1 illustrates that the first alignment post 150 is a single layer, but example embodiments are not limited thereto. For example, according to some example embodiments, the first alignment post 150 may have a multi-layer structure.

According to some example embodiments, the first alignment post 150 may be used to align the second chips 200. For example, the second chips 200 may be aligned on the bottom surface 300BS of the first molding film using the first alignment post 150 as a reference point.

According to some example embodiments, the alignment pad 130 and the first alignment post 150 may include a metal material, but are not be electrically connected to the first chip group 100G and the second chip group 200G.

Referring to FIG. 1, in an example embodiment, the width of the end portion of the first part 121 of the first distribution post 120 facing the package substrate 50 is greater than the width of the end portion of the second part 122 of the first distribution post 120 facing the first chip 100 in the second direction D2. In an example embodiment, the width of the end portion of the first alignment post 150 facing the package substrate 50 and the width of the end portion of the first part 121 of the first distribution post 120 facing the package substrate 50 are different from each other in the second direction D2. In an example embodiment, the width of the end portion of the first alignment post 150 facing the package substrate 50 is greater than the width of the end portion of the first part 121 of the first distribution post 120 facing the package substrate 50 in the second direction D2. In an example embodiment, the surface of the end portion of the first alignment post 150 facing the package substrate 50 is coplanar with the surface of the end portion of the first part 121 of the first distribution post 120 facing the package substrate 50. In an example embodiment, a surface of the first molding film 300 facing the package substrate 50 is coplanar with a surface of the end portion of the first alignment post 150 facing the package substrate 50.

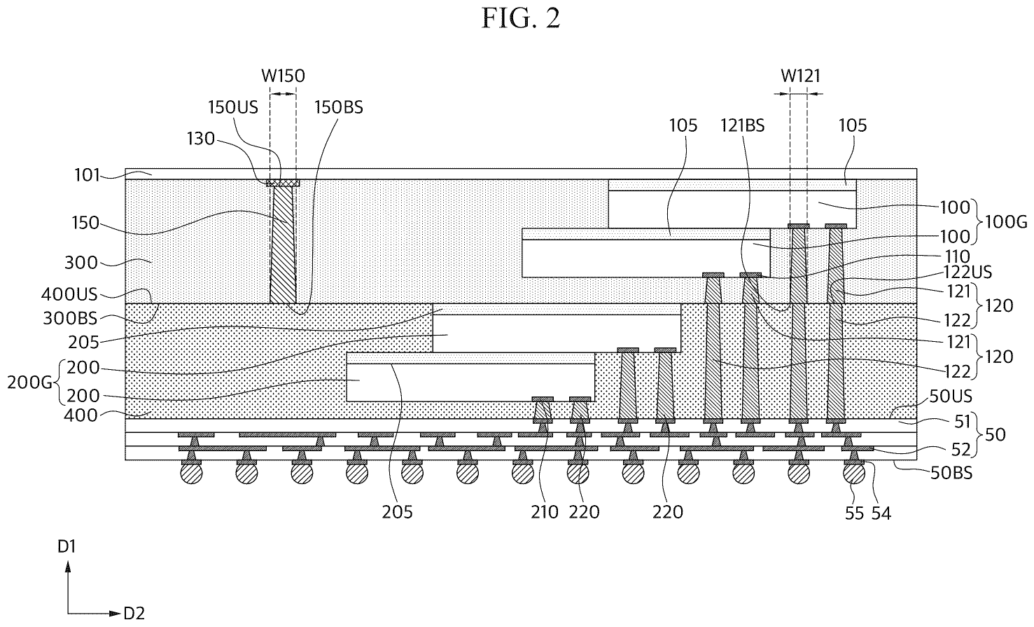

FIG. 2 is a drawing illustrating a semiconductor package according to an example embodiment. For convenience of explanation, a further description of components and technical aspects previously described with reference to FIG. 1 will be omitted or briefly described.

Referring to FIG. 2, according to some example embodiments, the semiconductor package does not include the dummy pads 140 (of FIG. 1). The alignment pad 130 may be disposed on the insulating film 101 within the first molding film 300, but not the dummy pads 140 (of FIG. 1).

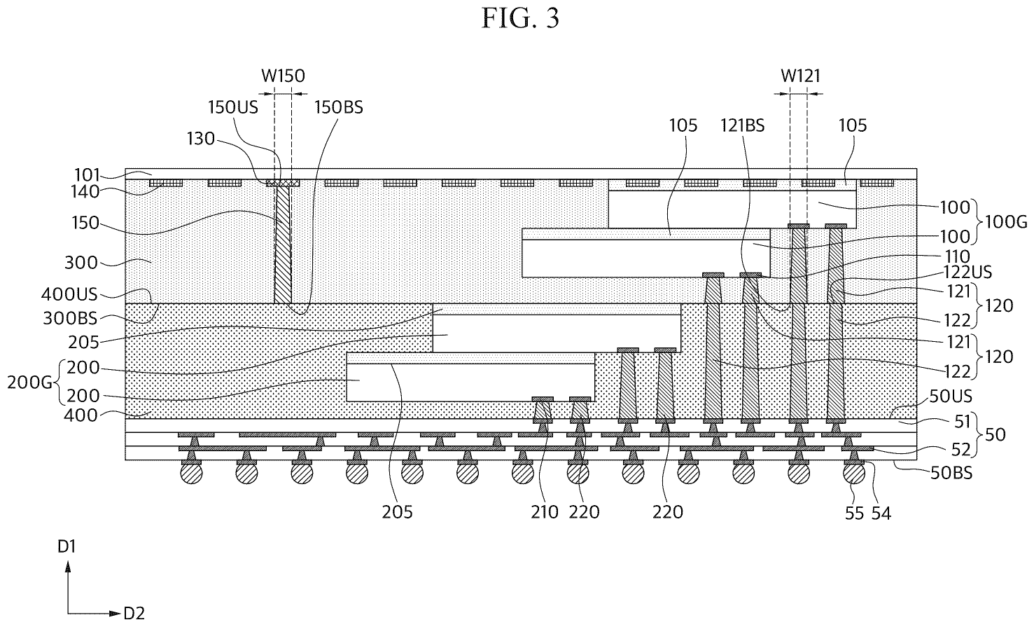

FIG. 3 is a drawing illustrating a semiconductor package according to an example embodiment. For convenience of explanation, a further description of components and technical aspects previously described with reference to FIG. 1 will be omitted or briefly described.

Referring to FIG. 3, in the second direction D2, the maximum width W150 of the first alignment post 150 may be the same as the maximum width W121 of the first part 121 of the first distribution post 120. The width of the bottom surface 150BS of the first alignment post 150 and the width of the bottom surface 121BS of the first part of the first distribution post 120 may be the same in the second direction D2. For example, the width of the bottom surface 150BS of the first alignment post 150 may be the same as the width of the bottom surface 121BS of the first part.

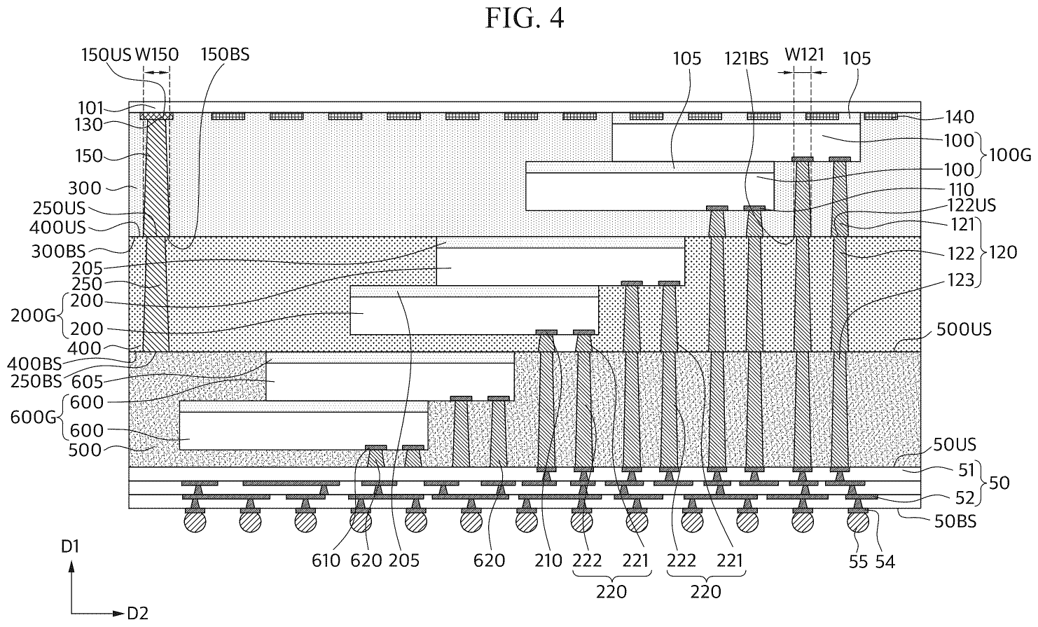

FIG. 4 is a drawing illustrating a semiconductor package according to an example embodiment. For convenience of explanation, a further description of components and technical aspects previously described with reference to FIG. 1 will be omitted or briefly described.

Referring to FIG. 4, according to some example embodiments, the semiconductor package may further include the first alignment post 150, a second alignment post 250, a third molding film 500 and a third chip group 600G.

According to some example embodiments, the first alignment post 150 may correspond to the first alignment post 150 described with reference to FIG. 1. The first alignment post 150 according to example embodiments is described further with reference to FIG. 4.

According to some example embodiments, the first distribution post 120 may include the first part 121, the second part 122 and a third part 123. The first part 121 may penetrate the first molding film 300. The second part 122 may penetrate the second molding film 400. The third part 123 may penetrate the third molding film 500. Each of the first part 121, the second part 122 and the third part 123 may extend in the first direction D1. The first part 121, the second part 122 and the third part 123 may be connected to each other in the first direction D1.

According to some example embodiments, the second distribution post 220 may include a fourth part 221 and a fifth part 222. The fourth part 221 and the fifth part 222 may be distinguished based on the interface where the second molding film 400 and the third molding film 500 come into contact.

According to some example embodiments, the fourth part 221 may be disposed within the second molding film 400. The fourth part 221 may penetrate the second molding film 400. The fourth part 221 may be surrounded by the second molding film 400. The fourth part 221 may overlap the second molding film 400 in the second direction D2.

According to some example embodiments, the fourth part 221 may be disposed on the fifth part 222 in the first direction D1. For example, the fourth part 221 may be disposed on the upper surface of the fifth part 222 in the first direction D1. The fourth part 221 may be connected to the fifth part 222.

According to some example embodiments, the fifth part 222 may be disposed within the third molding film 500. The fifth part 222 may penetrate the third molding film 500. The fifth part 222 may be surrounded by the third molding film 500. The fifth part 222 may overlap the third molding film 500 in the second direction D2.

According to some example embodiments, the fifth part 222 may be disposed on a lower portion of the fourth part 221 in the first direction D1. For example, the fifth part 222 may be disposed on the bottom surface of the fourth part 221 in the first direction D1. The fifth part 222 may be connected to the fourth part 221.

According to some example embodiments, the fourth part 221 and the fifth part 222 may be in direct contact with each other. For example, the fourth part 221 and the fifth part 222 may be directly connected to each other without intervening elements. The bottom surface of the fourth part 221 and the upper surface of the fifth part 222 may contact each other. The bottom surface of the fourth part 221 may refer to one side of the fourth part 221 facing the package substrate 50. The upper surface of the fifth part 222 may refer to one side of the fifth part 222 facing the second chip 200.

According to some example embodiments, the first alignment post 150 may be disposed on the second alignment post 250. The first alignment post 150 may extend in the first direction D1 between the second alignment post 250 and the alignment pad 130.

According to some example embodiments, the second alignment post 250 may penetrate the second molding film 400. The second alignment post 250 may overlap the second molding film 400 in the second direction D2. The second alignment post 250 may be surrounded by the second molding film 400. The second alignment post 250 may overlap the third molding film 500 in the first direction D1.

According to some example embodiments, the second alignment post 250 may overlap the first alignment post 150 in the first direction D1. The second alignment post 250 may extend in the first direction D1 between the first alignment post 150 and the third molding film 500. For example, an upper surface 250US of the second alignment post 250 may contact the bottom surface 150BS of the first alignment post. The second alignment post 250 may be aligned using the first alignment post 150.

According to some example embodiments, the second alignment post 250 does not penetrate the first molding film 300 and the third molding film 500. According to some example embodiments, the upper surface 250US of the second alignment post 250 does not contact the first molding film 300. A bottom surface 250BS of the second alignment post 250 may be covered by the third molding film 500. The bottom surface 250BS of the second alignment post 250 may contact the third molding film 500.

According to some example embodiments, the second alignment post 250 does not overlap a third chip 600 in the first direction D1. The second alignment post 250 may be spaced apart from the second chip 200 in the second direction D2.

According to some example embodiments, the bottom surface 250BS of the second alignment post, a bottom surface 400BS of the second molding film, the bottom surface of the second part 122 of the first distribution post 120, and the bottom surface of the fourth part 221 of the second distribution post 220 may be arranged on the same plane. This alignment may result from a manufacturing process of semiconductor packages, in which the grinding operation is performed on the second alignment post 250, the second molding film 400, the second part 122 of the first distribution post 120, and the fourth part 221 of the second distribution post 220 through the same process.

According to some example embodiments, the second alignment post 250 may be used to align the third chip 600. For example, the third chip 600 may be aligned on the bottom surface 400BS of the second molding film using the second alignment post 250 as a reference point.

According to some example embodiments, the third molding film 500 may be disposed at a lower portion on the second molding film 400. In the first direction D1, the third molding film 500 may be disposed on the bottom surface 400BS of the second molding film. The third molding film 500 may cover the bottom surface 250BS of the second alignment post. The third molding film 500 may overlap the second alignment post 250 in the first direction D1. The third molding film 500 may be disposed between the second molding film 400 and the package substrate 50. The third molding film 500 may be disposed on the package substrate 50. The third molding film 500 may cover the upper surface 50US of the package substrate.

According to some example embodiments, the third molding film 500 may surround the third chip group 600G. The third molding film 500 may cover the third chip group 600G. The third molding film 500 may surround the third chip 600, the fifth part 222 of the second distribution post 220, and the third part 123 of the first distribution post 120.

According to some example embodiments, the second molding film 400 and the third molding film 500 may contact each other. For example, the bottom surface 400BS of the second molding film and an upper surface 500US of the third molding film may contact each other. The bottom surface 400BS of the second molding film may refer to one side of the second molding film 400 facing the package substrate 50. The upper surface 500US of the third molding film may refer to one side of the third molding film 500 facing the second chip group 200G.

According to some example embodiments, the third chip group 600G may be disposed on the package substrate 50 in the first direction D1. The third chip group 600G may be disposed at lower portions of the first chip group 100G and the second chip group 200G in the first direction D1. The third chip group 600G may be disposed between the second chip group 200G and the package substrate 50. The third chip group 600G may be disposed closer to the package substrate 50 in the first direction D1 than the first chip group 100G and the second chip group 200G. For example, in the first direction D1, a distance between the third chip group 600G and the package substrate 50 may be less than a distance between the second chip group 200G and the package substrate 50, and may be less than a distance between the first chip group 100G and the package substrate 50. The third chip group 600G may be disposed within the third molding film 500.

According to some example embodiments, the third chip group 600G may include at least one third chip 600. For example, the third chip group 600G may include multiple third chips 600. For example, the third chip group 600G may include two third chips 600. The third chips 600 may be disposed on the package substrate 50 in the first direction D1. For example, the third chips 600 may be stacked on each other in the first direction D1. Although FIG. 4 illustrates that the third chip group 600G includes two third chips 600, example embodiments are not limited thereto. For example, according to some example embodiments, the third chip group 600G may include only one third chip 600 or may include three or more third chips 600.

According to some example embodiments, the third chip 600 may include a third connection pad 610. A third distribution post 620 may be disposed on the third connection pad 610.

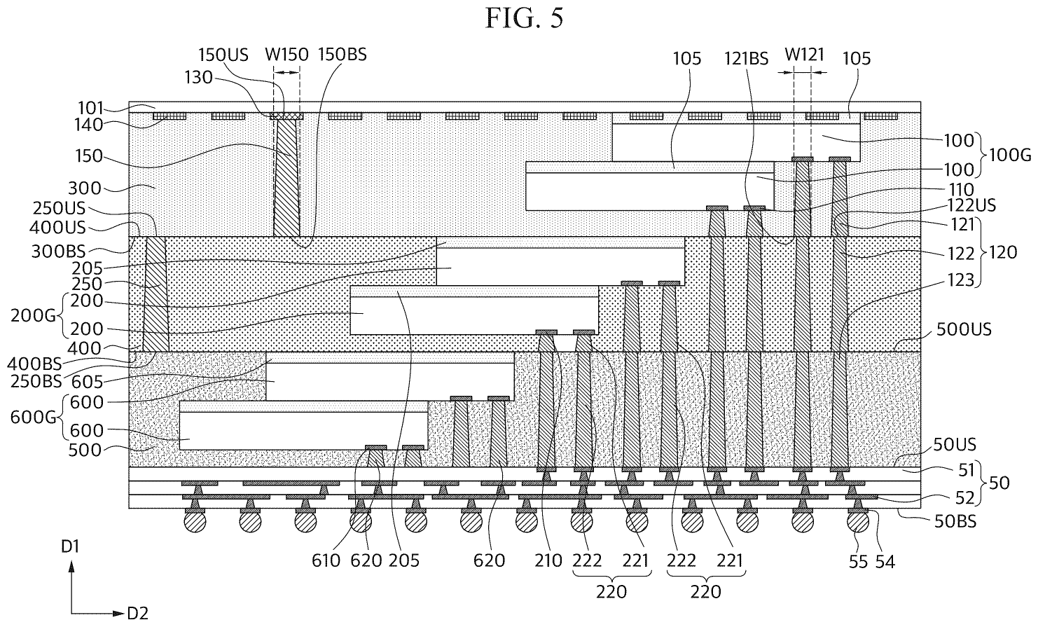

FIG. 5 is a drawing illustrating a semiconductor package according to an example embodiment. For convenience of explanation, a further description of components and technical aspects previously described with reference to FIG. 4 will be omitted or briefly described.

Referring to FIG. 5, according to some example embodiments, the second alignment post 250 does not overlap the first alignment post 150 in the first direction D1. The second alignment post 250 may overlap the first molding film 300 and the third molding film 500 in the first direction D1. The second alignment post 250 may extend in the first direction D1 between the first molding film 300 and the third molding film 500. The upper surface 250US of the second alignment post 250 may be covered by the first molding film 300. The bottom surface 150BS of the first alignment post 150 may be covered by the second molding film 400.

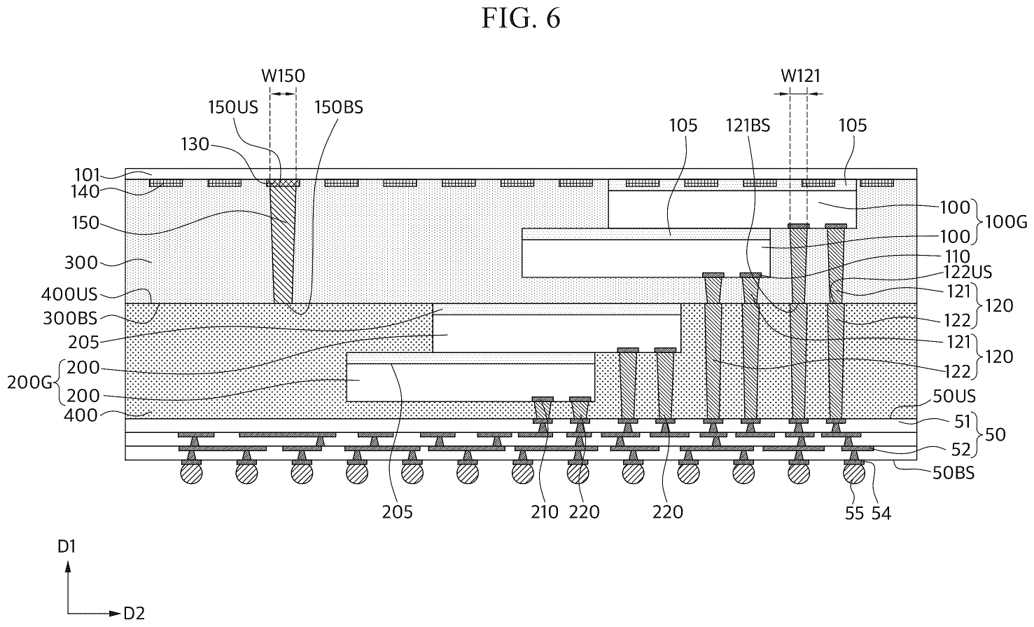

FIG. 6 is a drawing illustrating a semiconductor package according to an example embodiment. For convenience of explanation, a further description of components and technical aspects previously described with reference to FIG. 1 will be omitted or briefly described.

Referring to FIG. 6, as the first alignment post 150, the first part 121 of the first distribution post 120 and the second part 122 and the second distribution post 220 get closer to the package substrate 50 in the first direction D1, the width in the second direction D2 may decrease. For example, in a cross-sectional view along the first direction D1 and the second direction D2, the first alignment post 150, each of the first part 121 and the second part 122, and the second distribution post 220 may have an inverse trapezoidal shape.

According to some example embodiments, the bottom surface 121BS of the first part and the upper surface 122US of the second part may have different widths in the second direction D2. For example, in the second direction D2, the width of the bottom surface 121BS of the first part may be smaller than the width of the upper surface 122US of the second part.

According to some example embodiments, in the second direction D2, the maximum width W150 of the first alignment post 150 may be different from the maximum width W121 of the first part 121 of the first distribution post 120. The width of the upper surface 150US of the first alignment post 150 and the width of the upper surface 121US of the first part of the first distribution post 120 may be different in the second direction D2. For example, the width of the upper surface 150US of the first alignment post 150 may be larger than the width of the upper surface 121US of the first part.

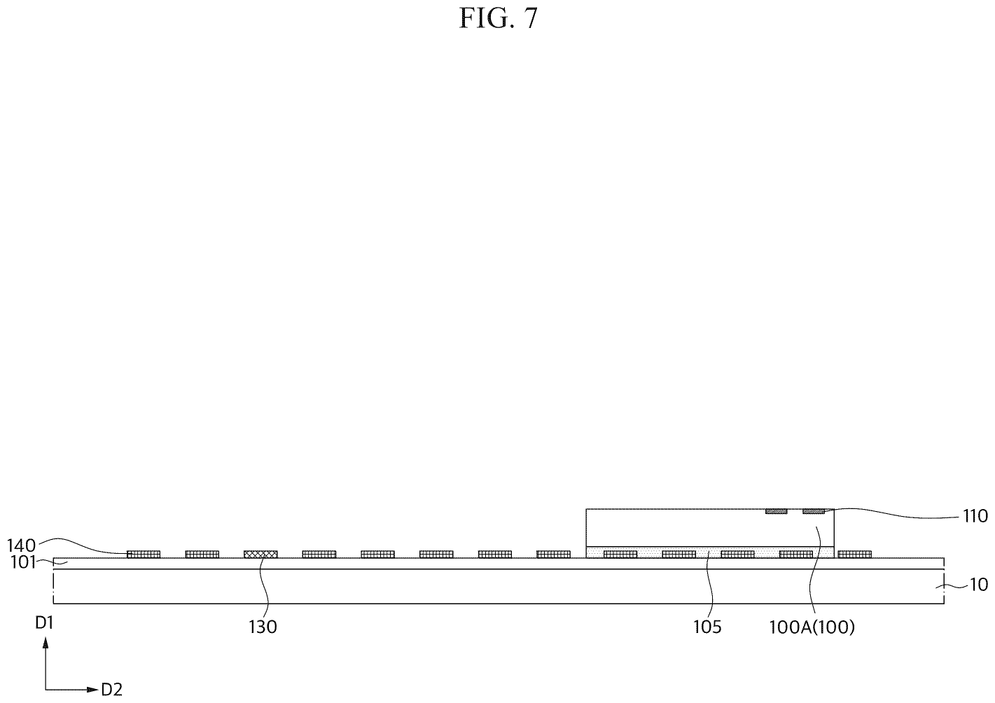

FIGS. 7 to 20 are drawings illustrating intermediate operations performed in a method of manufacturing a semiconductor package according to some example embodiments.

Referring to FIG. 7, the insulating film 101, the alignment pad 130, the dummy pad 140, and a first chip 100A may be formed on a carrier substrate 10.

According to some example embodiments, the carrier substrate 10 may be an insulating substrate including glass or polymer, or a conductive substrate including metal. The carrier substrate 10 may be a support substrate on which the insulating film 101, the alignment pad 130, the dummy pad 140, and the first chip 100A are arbitrarily formed during the process of manufacturing a semiconductor package. The first chip 100A may be attached to the insulating film 101 and the dummy pad 140 through the first adhesive layer 105. The first chip 100A may be formed on the insulating film 101 so as not to cover the alignment pad 130. The first chip 100A may be disposed so that the first connection pad 110 is exposed. For example, the first chip 100A may be disposed on the carrier substrate 10 such that one side of the first chip 100A on which the first connection pad 110 is disposed does not face the carrier substrate 10.

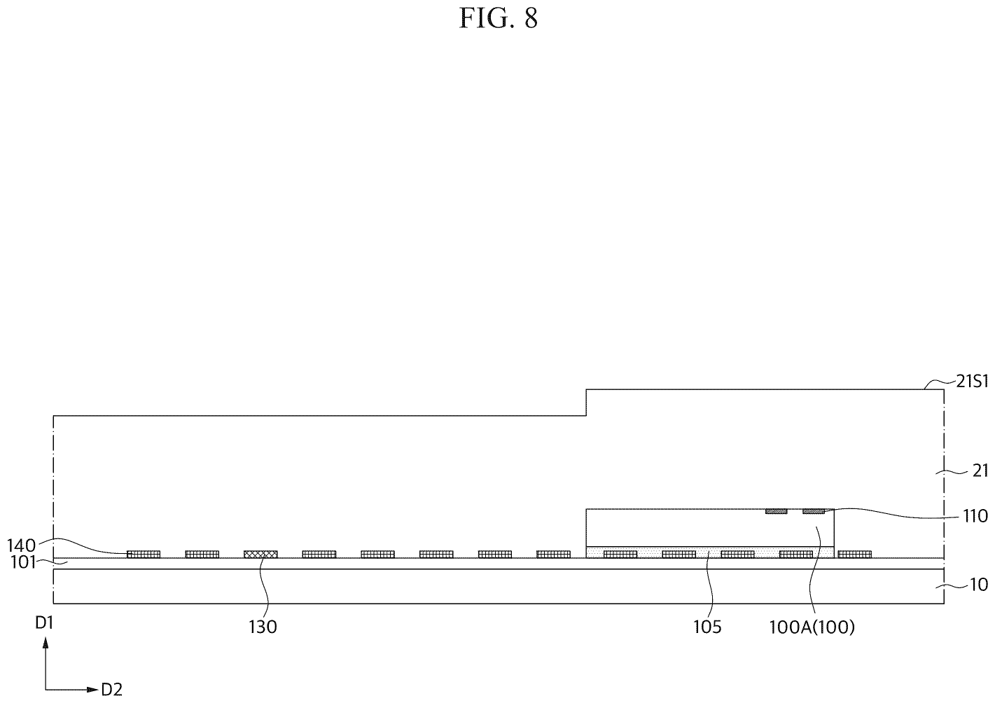

Referring to FIG. 8, a first resist film 21 may be formed on the insulating film 101, the alignment pad 130, the dummy pad 140, and the first chip 100A.

According to some example embodiments, the first resist film 21 may cover the insulating film 101, the alignment pad 130, the dummy pad 140, and the first chip 100A on the carrier substrate 10. The first resist film 21 may include, for example, a photoresist material.

According to some example embodiments, the first resist film 21 may be formed along the step of the insulating film 101 and the first chip 100A. For example, a first side 21S1 of the first resist film extending along the profile of the step of the insulating film 101 and the first chip 100A may have a step. However, example embodiments are not limited thereto. For example, according to some example embodiments, the first side 21S1 of the first resist film may extend parallel to the carrier substrate 10 without a step. The first side 21S1 of the first resist film may refer to the side opposite to the side of the first resist film 21 facing the carrier substrate 10.

For example, according to some example embodiments, the first side 21S1 of the first resist film 21 may follow the contour of the step in the insulating film 101 and the first chip 100A and may have a stepped profile. However, embodiments are not limited to this configuration. For example, according to some example embodiments, the first side 21S1 of the first resist film may instead extend parallel to the carrier substrate 10 without any step. The first side 21S1 refers to the side of the first resist film 21 that is opposite the side facing the carrier substrate 10.

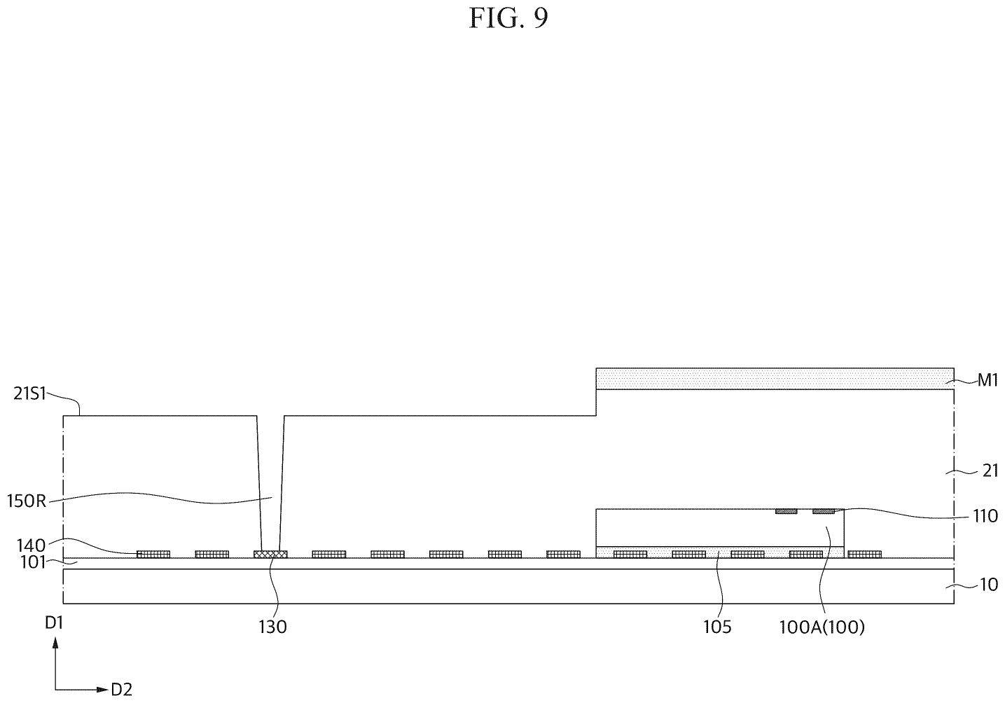

Referring to FIG. 9, an alignment post recess 150R may be formed.

According to some example embodiments, the alignment post recess 150R may penetrate the first resist film 21. The alignment pad 130 may be exposed through the alignment post recess 150R. The alignment post recess 150R may be formed on the alignment pad 130 and the insulating film 101. For example, the alignment post recess 150R may be formed on the alignment pad 130.

According to some example embodiments, a first mask M1 may be formed on some area of the first resist film 21 that overlaps the first chip 100A in the first direction D1. For example, when the first resist film 21 is formed along the step profile of the insulating film 101 and the first chip 100A, in the first direction D1, the thickness of the first resist film 21 formed on the insulating film 101 on which the first chip 100A is not placed may be different from the thickness of the first resist film 21 formed on the first chip 100A. Therefore, in order to prevent other recesses from being formed on the first chip 100A when the alignment post recess 150R is formed, the first mask M1 may block some areas of the first resist film 21.

According to some example embodiments, the alignment post recess 150R may be formed through an exposure process. For example, the alignment post recess 150R may be formed by exposing and developing using a mask pattern. When the alignment post recess 150R is formed, the shape of the alignment post recess 150R may vary depending on whether the exposed portion or the unexposed portion of the first resist film 21 is removed.

For example, when the exposed portion of the first resist film 21 is removed to form the alignment post recess 150R, the alignment post recess 150R may have a width that decreases in the second direction D2 as the alignment post recess 150R approaches the alignment pad 130 from the first side 21S1 of the first resist film. On the other hand, when the unexposed portion of the first resist film 21 is removed to form the alignment post recess 150R, as the alignment post recess 150R gets closer to the alignment pad 130 from the first side 21S1 of the first resist film, the width of the alignment post recess 150R in the second direction D2 may increase.

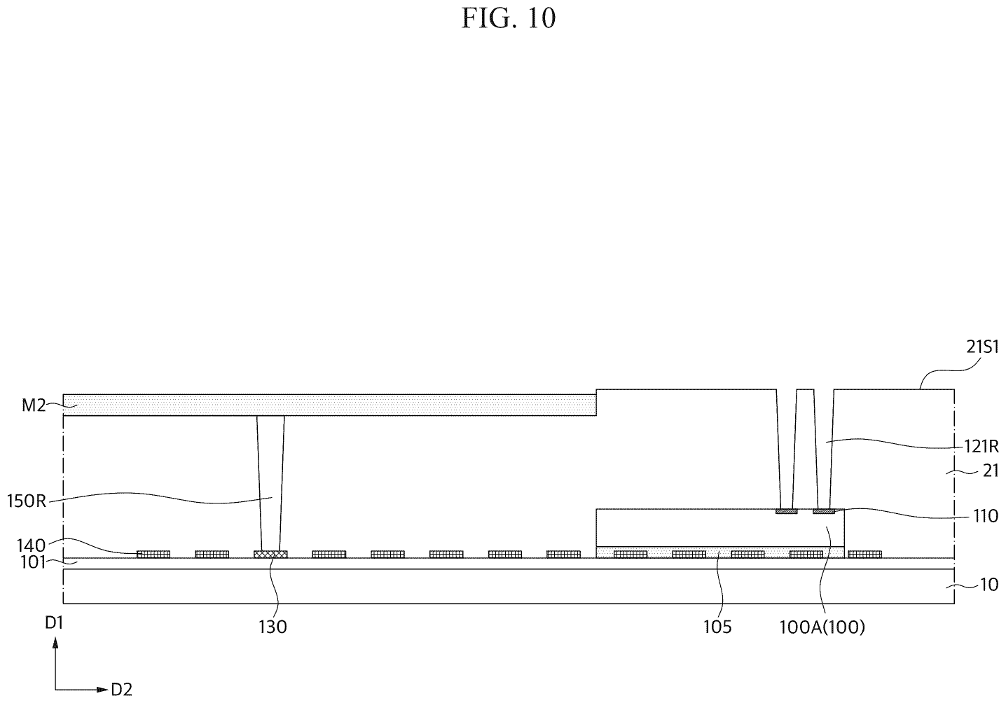

Referring to FIG. 10, a first part recess 121R may be formed.

According to some example embodiments, the first part recess 121R may penetrate the first resist film 21. The first connection pad 110 may be exposed through the first part recess 121R. The first part recess 121R may be formed on the first chip 100A.

According to some example embodiments, a second mask M2 may be formed on some areas of the first resist film 21 where the first chip 100A is not disposed. Therefore, when the first part recess 121R is formed, in order to prevent other recesses from being formed on the insulating film 101 and the dummy pad 140 in the area where the first chip 100A is not placed, the second mask M2 may block some areas of the first resist film 21. Since the depth of the alignment post recess 150R and the first part recess 121R penetrating the first resist film 21 are different, the alignment post recess 150R and the first part recess 121R may be formed sequentially.

According to some example embodiments, in the second direction D2, the width of the first part recess 121R may be smaller than the width of the alignment post recess 150R. For example, in the first side 21S1 of the first resist film, the width of the first part recess 121R in the second direction D2 may be smaller than the width of the alignment post recess 150R.

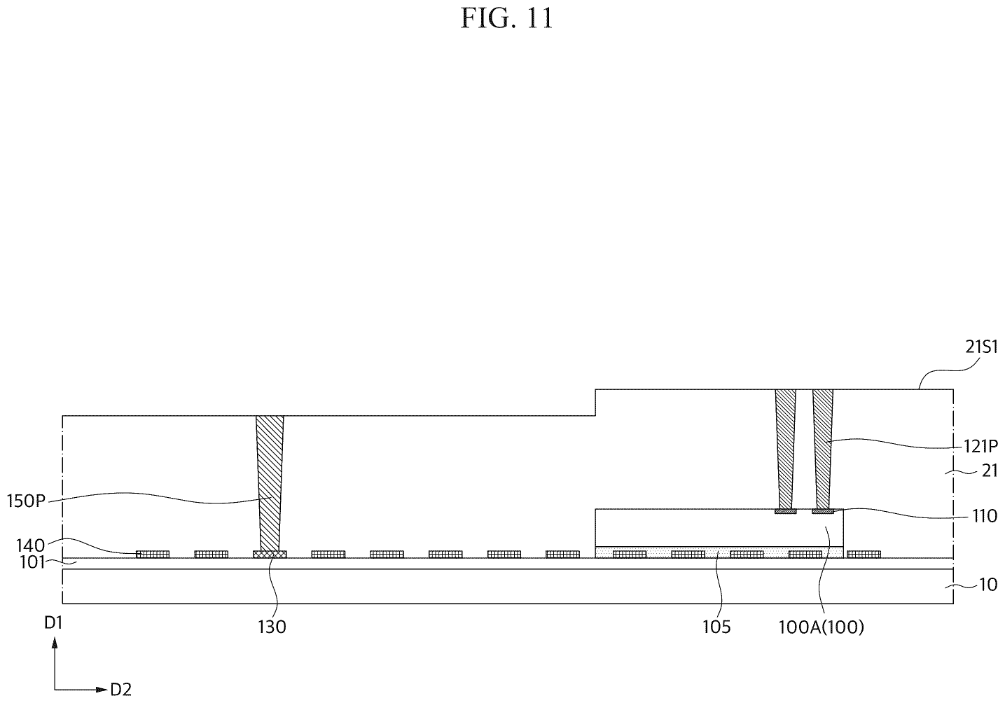

Referring to FIG. 11, a pre-first alignment post 150P and a pre first part 121P may be formed.

According to some example embodiments, the pre-first alignment post 150P may fill the alignment post recess 150R (of FIG. 10). The pre first part 121P may fill the first part recess 121R (of FIG. 10). FIG. 11 illustrates that the pre-first alignment post 150P and the pre first part 121P fill both the alignment post recess 150R (of FIG. 10) and the first part recess 121R (of FIG. 10), respectively, and the upper surface of the pre-first alignment post 150P and the upper surface of the pre first part 121P are disposed on the same plane as the first side 21S1 of the first resist film. However, example embodiments of the present disclosure are not limited thereto. For example, according to some example embodiments, the upper surface of the pre-first alignment post 150P and the upper surface of the pre first part 121P may be formed lower than the first side 21S1 of the first resist film.

According to some example embodiments, when the pre-first alignment post 150P and the pre first part 121P are formed, the pre first part 121P may be formed before the pre-first alignment post 150P. For example, since the width of the first part recess 121R (of FIG. 10) is smaller than the width of the alignment post recess 150R (of FIG. 10), the pre first part 121P may fill the first part recess 121R (of FIG. 10) faster than the pre-first alignment post 150P fills the alignment post recess 150R (of FIG. 10).

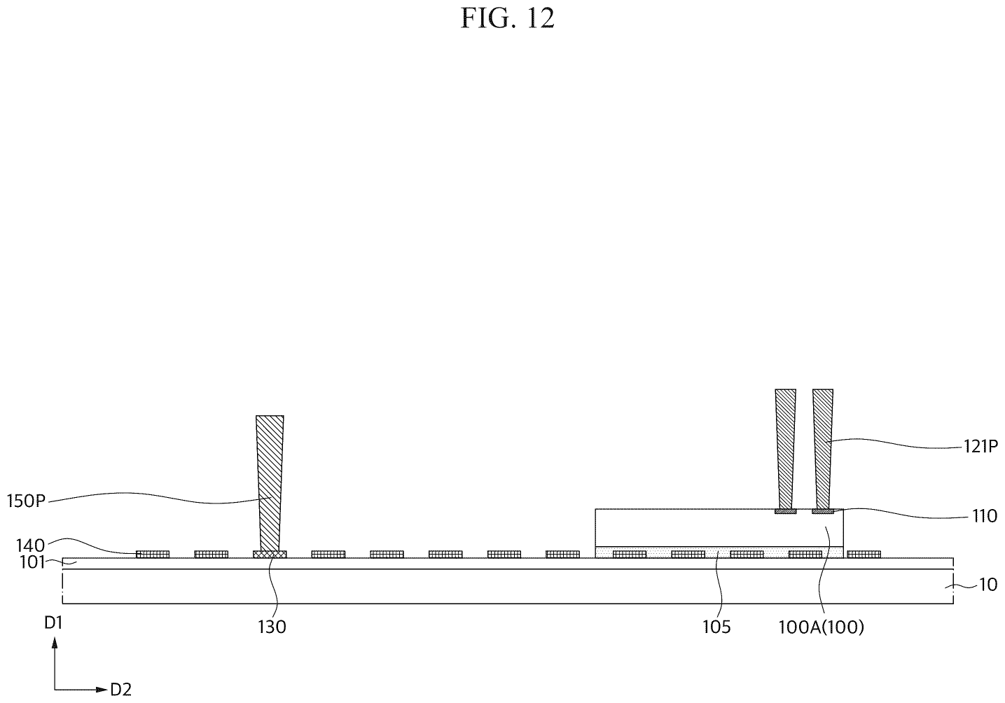

Referring to FIG. 12, the first resist film 21 (of FIG. 11) may be removed.

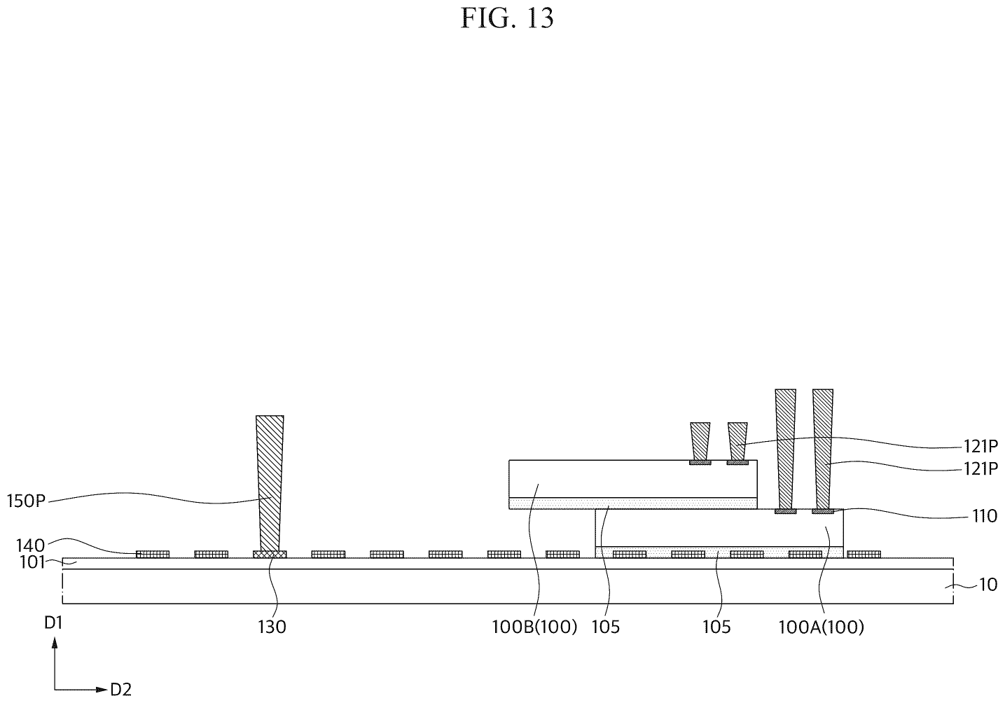

According to some example embodiments, when the first resist film 21 (of FIG. 11) is removed, the dummy pads 140, the insulating film 101, and the first chip 100A may be exposed again. Further, the pre-first alignment post 150P and the pre first part 121P may be exposed. Referring to FIG. 13, a first chip 100B may be formed.

According to some example embodiments, the first chip 100B may be stacked on the first chip 100A. The first chip 100B may be arranged offset by a certain distance from the first chip 100A in the second direction D2. Here, the first chip 100B may be disposed on the first chip 100A in a state where the pre first part 121P is already formed. For example, the pre first part 121P formed on the first chip 100B may be formed at wafer level. The first chip 100B, on which the pre first part 121P is formed, may be formed on the first chip 100A.

For example, the pre first part 121P on the first chip 100B and the pre first part 121P on the first chip 100A may have different lengths in the first direction D1. The pre first part 121P on the first chip 100B may be shorter than the pre first part 121P on the first chip 100A in the first direction D1. As a result, the pre first part 121P may be damaged when a relatively long pre first part 121P is first formed on the first chip 100A and then picked and disposed on the carrier substrate 10. On the contrary, the first chip 100B in which a relatively short pre first part 121P is formed may be stably picked and disposed on the carrier substrate 10.

According to some example embodiments, the pre first part 121P on the first chip 100A may be formed in a fab-out state. For example, the pre first part 121P on the first chip 100A may be formed on the first chip 100A after the first chip 100A is disposed on the carrier substrate 10. The pre first part 121P on the first chip 100B may be formed in a fab-in state. For example, the pre first part 121P on the first chip 100B may be formed on the first chip 100B before the first chip 100B is disposed on the carrier substrate 10. However, example embodiments are not limited thereto. For example, according to some example embodiments, after both the pre first part 121P on the first chip 100A and the pre first part 121P on the first chip 100B are formed in the fab-in state, the first chip 100A and the first chip 100B may be picked and disposed on the carrier substrate 10.

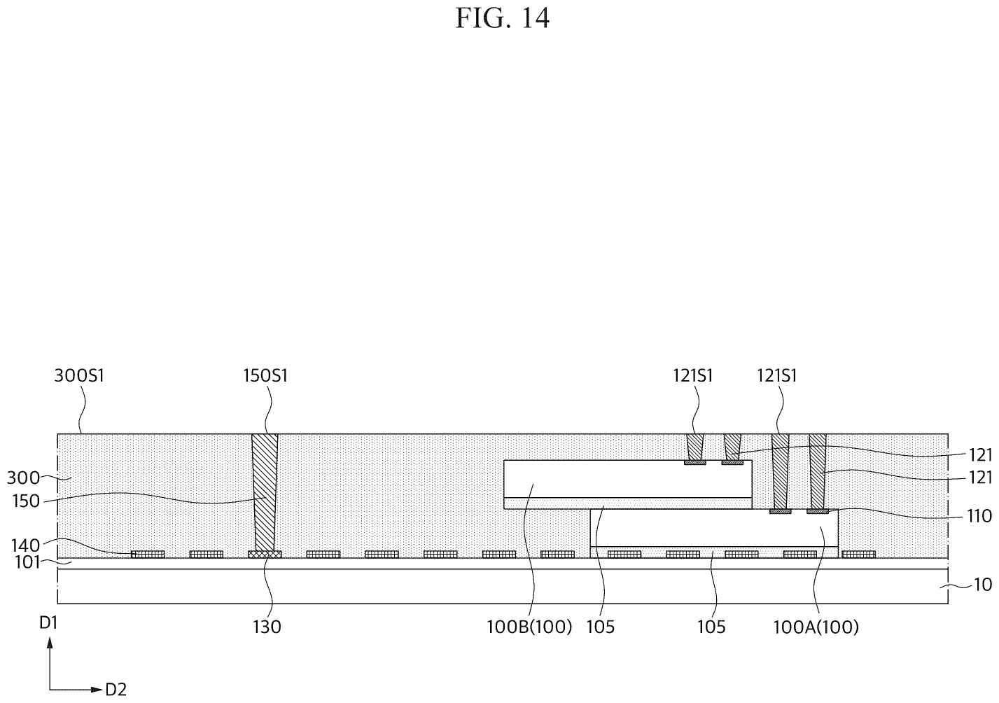

According to some example embodiments, when the first chip 100B is disposed on the first chip 100A, the first chip 100B may be aligned using the alignment pad 130. In an example embodiment, when viewed in the first direction D1, the alignment pad 130 is distinguishable in a cross section from the insulating film 101. In an example embodiment, when viewed in the first direction D1, the alignment pad 130 has a step difference from the insulating film 101, and thus, the alignment pad 130 and the insulating film 101 may be distinguished from each other. In an example embodiment, by illuminating the alignment pad 130 with light and measuring the light reflected or scattered from the alignment pad 130 and its boundaries, the position of the first chip 100B relative to the alignment pad 130 may be detected. Therefore, a position of the first chip 100B may be aligned using the alignment pad 130 as a reference point. Referring to FIG. 14, the first molding film 300 may be formed.

According to some example embodiments, the first molding film 300 may surround the first chip 100, the pre-first alignment post 150P (of FIG. 13) and the pre first part 121P (of FIG. 13). During the grinding operation performed on all of the first molding film 300, the pre-first alignment post 150P (of FIG. 13) and the pre first part 121P (of FIG. 13), a first side 300S1 of the first molding film, a first side 150S1 of the alignment post, and a first side 121S1 of the first part may be disposed on the same plane. The first side 300S1 of the first molding film may correspond to the bottom surface 300BS of the first molding film of FIG. 1. The first side 150S1 of the first alignment post 150 may correspond to the bottom surface 150BS of the alignment post in FIG. 1. The first side 121S1 of the first part may correspond to the bottom surface 121BS of the first part of FIG. 1.

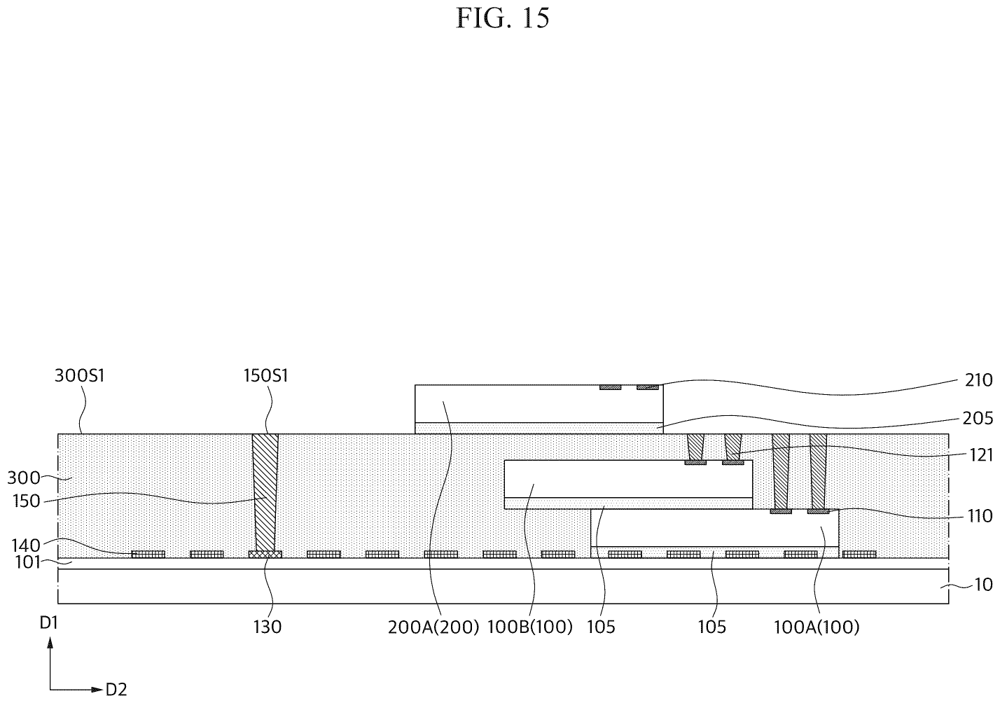

Referring to FIG. 15, a second chip 200A may be formed on the first molding film 300.

According to some example embodiments, the second chip 200A may be formed on the first side 300S1 of the first molding film. The second chip 200A may be aligned on the first molding film 300 using the first alignment post 150. For example, the second chip 200A may be aligned with the first chip 100 using the first side 150S1 of the alignment post. For example, since the first side 300S1 of the first molding film and the first side 150S1 of the alignment post are distinguished, the position of the second chip 200A may be aligned using the first side 150S1 of the alignment post as a reference point.

Referring to a comparative example, since the first molding film 300 covers the alignment pad 130, the alignment pad 130 may not be used as a reference for alignment when forming the second chip 200A. In this case, the intermediate wiring layer including an intermediate alignment pad may be formed on the first molding film 300. Meanwhile, when the intermediate wiring layer is formed, as the thickness of the semiconductor package increases in the first direction D1, miniaturization of the semiconductor package may be limited. Further, when the intermediate alignment pad is formed in the intermediate wiring layer, since the middle alignment pad is aligned using the first part 121 disposed on the first chip 100B, the alignment is doubled, which may lower the alignment accuracy.

In contrast, according to some example embodiments, since a separate intermediate wiring layer is not formed on the first molding film 300, the thickness of the semiconductor package in the first direction D1 is reduced, and the semiconductor package may be miniaturized. Further, since the first alignment post 150 formed directly on the alignment pad 130 is used as a reference, the alignment accuracy of the second chip 200A may be improved.

According to some example embodiments, the second chip 200A may be attached to the first molding film 300 via the second adhesive layer 205. The second adhesive layer 205 may be in direct contact with the first side 300S1 of the first molding film. The second chip 200A may be arranged offset from the first chip 100 by a certain distance in the second direction D2. Therefore, according to some example embodiments, the first part 121 does not overlap the second chip 200A in the first direction D1.

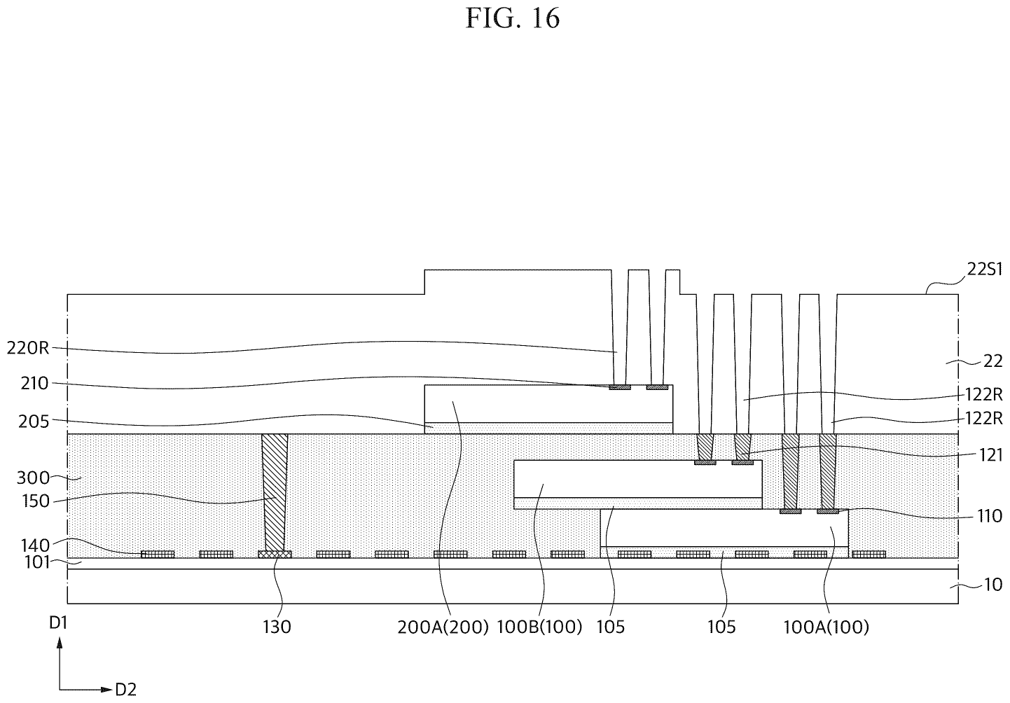

Referring to FIG. 16, a second resist film 22 may be formed on the first molding film 300, and a second distribution post recess 220R and a second part recess 122R may be formed within the second resist film 22.

According to some example embodiments, the second resist film 22 may cover the second chip 200A on the first molding film 300. The second resist film 22 may be formed along the step of the first molding film 300 and the second chip 200A. For example, a first side 22S1 of the second resist film extending along the step profile of the first molding film 300 and the second chip 200A may have a step. However, example embodiments are not limited thereto. For example, according to some example embodiments, the first side 22S1 of the second resist film may extend parallel to the first molding film 300 without a step. The first side 22S1 of the second resist film may refer to the side opposite to the side facing the carrier substrate 10 of the second resist film 22.

According to some example embodiments, the second distribution post recess 220R and the second part recess 122R may be formed sequentially. For example, similar to how the alignment post recess 150R (of FIG. 9) and the first part recess 121R (of FIG. 10) are sequentially formed using the first mask M1 (of FIG. 9) and the second mask M2 (of FIG. 10), the second distribution post recess 220R and the second part recess 122R may also be formed sequentially using a mask. Since the depths of the second distribution post recess 220R and the second part recess 122R penetrating the second resist film 22 are different, the second distribution post recess 220R and the second part recess 122R may be formed sequentially.

According to some example embodiments, the second distribution post recess 220R may be formed on the second connection pad 210 of the second chip 200A. The second connection pad 210 may be exposed through the second distribution post recess 220R. The second part recess 122R may be formed on the first part 121. The first side 121S1 (of FIG. 14) of the first part may be exposed through the second part recess 122R.

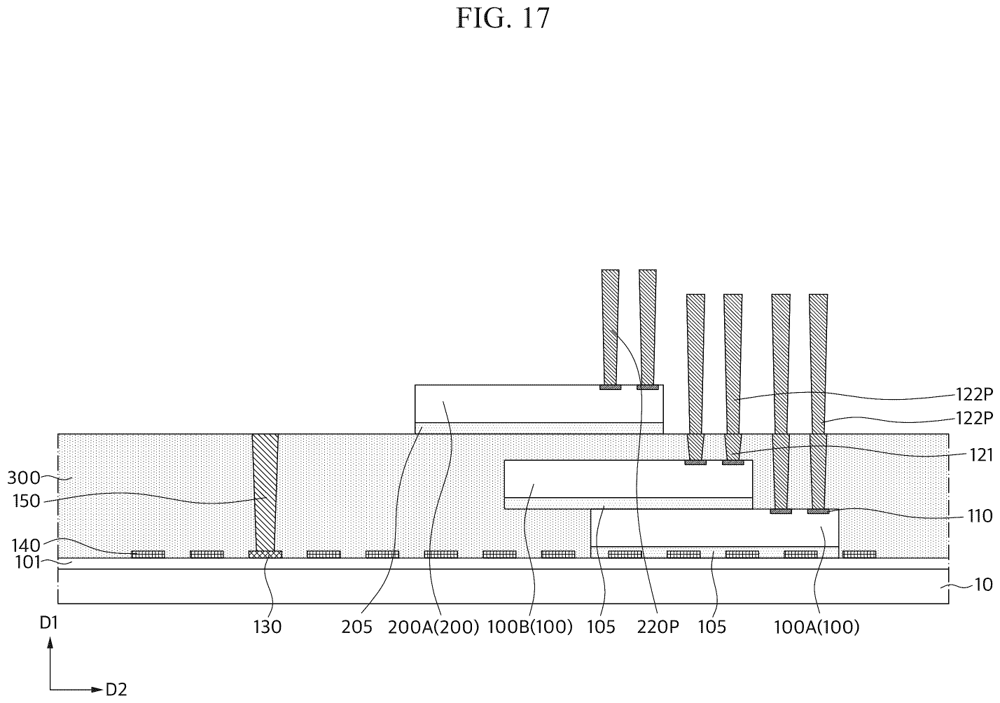

Referring to FIG. 17, a second pre distribution post 220P and a pre second part 122P may be formed.

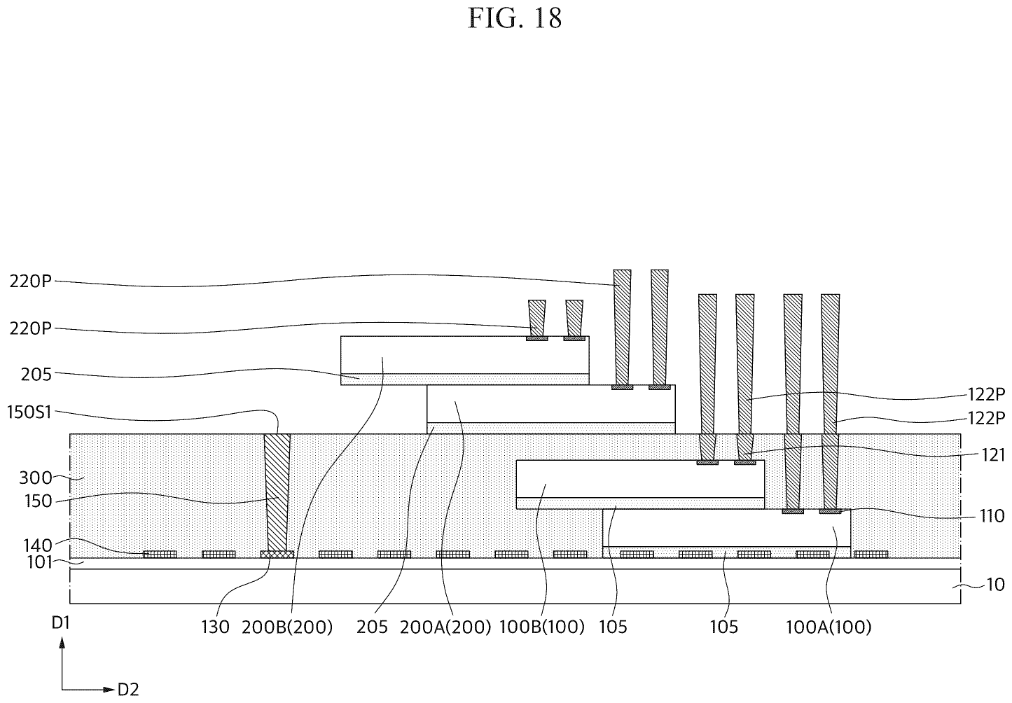

According to some example embodiments, the second pre-distribution post 220P may fill the second distribution post recess 220R (of FIG. 16). The pre second part 122P may fill the second part recess 122R (of FIG. 16). After the second pre distribution post 220P and the pre second part 122P are formed, the second resist film 22 (of FIG. 16) may be removed. Referring to FIG. 18, a second chip 200B may be formed.

According to some example embodiments, the second chip 200B may be stacked on the second chip 200A. The second chip 200B may be arranged offset by a certain distance from the second chip 200A in the second direction D2. Here, the second chip 200B may be disposed on the second chip 200A when the second pre-distribution post 220P is already formed. For example, the second pre distribution post 220P formed on the second chip 200B may be formed at the wafer level.

According to some example embodiments, when placing the second chip 200B on the second chip 200A, the second chip 200B may be aligned using the first alignment post 150. The second chip 200B may be aligned with the second chip 200A using the first side 150S1 of the alignment post. Similarly, the first alignment post 150 formed directly on the alignment pad 130 is used as a reference, and thus, the alignment accuracy of the second chip 200B may be improved.

According to some example embodiments, the second chip 200, which is aligned using the first side 150S1 of the alignment post, does not overlap the first alignment post 150 in the first direction D1.

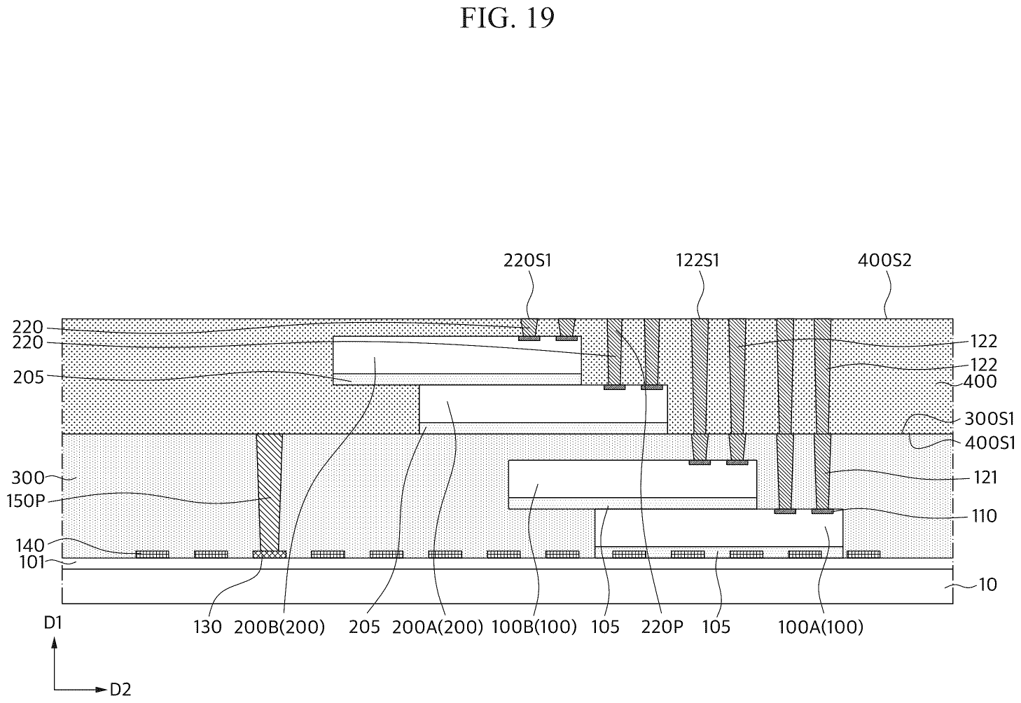

Referring to FIG. 19, the second molding film 400 may be formed.

According to some example embodiments, the second molding film 400 may be formed on the first molding film 300. An intermediate wiring layer including a separate alignment pad for aligning the second chip 200 is not disposed on the first molding film 300, and thus, the second molding film 400 may be in direct contact with the first molding film 300. For example, the first side 300S1 of the first molding film and a first side 400S1 of the second molding film may contact each other. The first side 400S1 of the second molding film may correspond to the upper surface 400US of the second molding film in FIG. 1.

According to some example embodiments, the second molding film 400 may surround the second chip 200, the second pre distribution post 220P (of FIG. 18) and the pre second part 122P (of FIG. 18). While the grinding operation is being performed on the second molding film 400, the second pre distribution post 220P (of FIG. 18) and the pre second part 122P (of FIG. 18), a second side 400S2 of the second molding film, a first side 220S1 of the second distribution post, and a first side 122S1 of the second part may be disposed on the same plane.

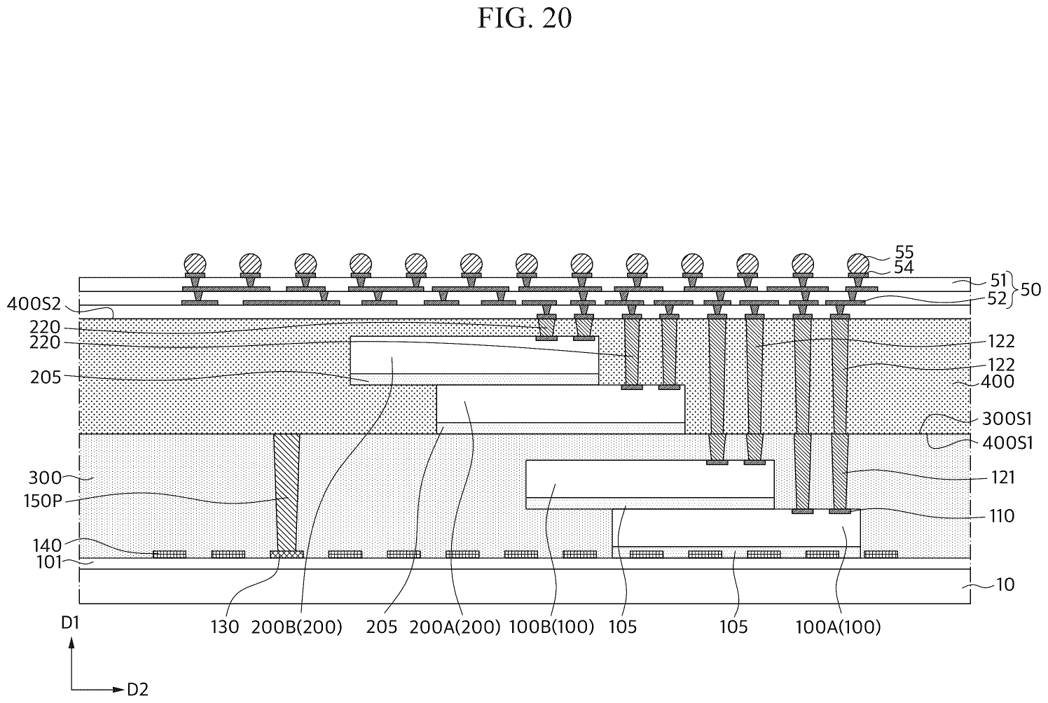

Referring to FIG. 20, the package substrate 50, the external connection pad 54, and the external connection terminal 55 may be formed on the second side 400S2 of the second molding film.

Further, the carrier substrate 10 may be removed and sawed to a predetermined size of the semiconductor package in the second direction D2.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A semiconductor package, comprising:
a package substrate;
a first chip group comprising at least one first chip spaced apart from the package substrate in a first direction perpendicular to a surface of the package substrate;
a second chip group comprising at least one second chip disposed between the package substrate and the first chip group;
a first molding film that surrounds the first chip group;
a second molding film that surrounds the second chip group; and
an alignment post that penetrates the first molding film,
wherein the second molding film covers a surface of an end portion of the alignment post facing the package substrate.

2. The semiconductor package of claim 1, wherein a surface of the first molding film facing the package substrate and a surface of the second molding film facing the first chip group contact each other.

3. The semiconductor package of claim 1, further comprising:
a first distribution post extending in the first direction between the at least one first chip and the package substrate,
wherein the first distribution post comprises:
a first part that penetrates the first molding film; and
a second part that penetrates the second molding film, and is connected to the first part, and
wherein a surface of an end portion of the first part facing the package substrate and a surface of an end portion of the second part facing the at least one first chip contact each other.

4. The semiconductor package of claim 3, wherein, along a second direction crossing the first direction, the at least one first chip and the at least second chip are offset from each other, and a width of the end portion of the first part facing the package substrate is greater than a width of the end portion of the second part facing the at least one first chip in the second direction.

5. The semiconductor package of claim 3, wherein, along a second direction crossing the first direction, the at least one first chip and the at least one second chip are offset from each other, and a width of the end portion of the alignment post facing the package substrate and a width of the end portion of the first part facing the package substrate are different from each other in the second direction.

6. The semiconductor package of claim 5, wherein the width of the end portion of the alignment post facing the package substrate is greater than the width of the end portion of the first part facing the package substrate in the second direction.

7. The semiconductor package of claim 3, wherein the alignment post and the first distribution post comprise a same material.

8. The semiconductor package of claim 3, wherein the surface of the end portion of the alignment post facing the package substrate is coplanar with the surface of the end portion of the first part facing the package substrate.

9. The semiconductor package of claim 1, wherein the alignment post does not overlap the at least one second chip in the first direction.

10. The semiconductor package of claim 1, further comprising:
an alignment pad disposed on the first chip group in the first direction and disposed in the first molding film,
wherein the alignment post extends between the alignment pad and the second molding film in the first direction.

11. The semiconductor package of claim 10, further comprising:
a plurality of dummy pads spaced apart from the alignment pad in a second direction crossing the first direction,
wherein the alignment pad does not overlap the first chip in the first direction, and
wherein at least one of the dummy pads overlaps the at least one first chip in the first direction.

12. The semiconductor package of claim 11, further comprising:
an insulting layer disposed on the alignment pad and the dummy pads in the first direction.

13. The semiconductor package of claim 1, wherein at least a portion of the first molding film is disposed between the at least one first chip, which is most adjacent to the second chip group among the first chip group, and the at least one second chip, which is most adjacent to the first chip group among the second chip group.

14. The semiconductor package of claim 1, wherein a surface of the first molding film facing the package substrate is coplanar with a surface of the end portion of the alignment post facing the package substrate.

15. A semiconductor package, comprising:
a package substrate;
a first chip group comprising at least one first chip spaced apart from the package substrate in a first direction perpendicular to a surface of the package substrate;
a second chip group comprising at least one second chip disposed between the package substrate and the first chip group;
a first molding film that surrounds the first chip group;
a second molding film that surrounds the second chip group;
an insulating film disposed on the first molding film in the first direction;
an alignment pad disposed in the first molding film and in contact with the insulating film; and
an alignment post that overlaps the alignment pad in the first direction,
wherein the alignment post penetrates the first molding film, and
wherein the alignment post overlaps the second molding film in the first direction.

16. The semiconductor package of claim 15, further comprising:
a first adhesive layer disposed on the at least one first chip; and
a second adhesive layer disposed on the at least one second chip, which is most adjacent to the first chip group among the second chip group,
wherein the second adhesive layer is in contact with the first molding film.

17. The semiconductor package of claim 15, wherein a surface of the first molding film facing the package substrate and a surface of the second molding film facing the first chip group are in contact with each other.

18. The semiconductor package of claim 15, wherein the at least one second chip is offset from the at least one first chip in a second direction crossing the first direction, and
wherein the alignment post is spaced apart from the at least one first chip in the second direction.

19. The semiconductor package of claim 18, wherein the alignment post does not overlap the at least one second chip in the first direction.

20. A semiconductor package, comprising:
a package substrate;
a first chip group comprising at least one first chip spaced apart from the package substrate in a first direction perpendicular to a surface of the package substrate;
a second chip group comprising at least one second chip disposed between the package substrate and the first chip group;
a first molding film that surrounds the first chip group;
a second molding film that surrounds the second chip group;
a first distribution post extending in the first direction between the at least one first chip and the package substrate;
a second distribution post extending in the first direction between the at least one second chip and the package substrate;
an alignment pad disposed on the first chip group in the first direction and disposed in the first molding film; and
an alignment post that overlaps the alignment pad in the first direction, penetrates the first molding film,
wherein the second molding film covers a surface of the alignment post facing the package substrate,
wherein the first distribution post comprises:
a first part that penetrates the first molding film; and
a second part that penetrates the second molding film, and is connected to the first part,
wherein a surface of an end portion of the first part facing the package substrate and a surface of an end portion of the second part facing the at least one first chip are in contact with each other,
wherein, in a second direction crossing the first direction, a width of the end portion of the first part facing the package substrate and a width of the end portion of the second part facing the first chip are different, and
wherein a surface of an end portion of the first molding film facing the package substrate and a surface of an end portion of the second molding film facing the first chip group are in contact with each other.
